(19) United States
(12) Patent Application Publication
(10) Pub. No.: US 2026/0239734 A1
(43) Pub. Date: Aug. 13, 2026

(54) SEMICONDUCTOR DEVICE INCLUDING Z-SHAPED MULTI-STACK TRANSISTOR STRUCTURE

(71) Applicant: SAMSUNG ELECTRONICS CO., LTD., Suwon-si (KR)

(72) Inventors: Beomjin Park, Halfmoon, NY (US); YoungGook Park, Wynantskill, NY (US); Edward Namkyu Cho, Slingerlands, NY (US); Jongmin Shin, Niskayuna, NY (US); Gwangsik Kim, Clifton Park, NY (US); Jinyoung Lim, Schenectady, NY (US); Kang-ill Seo, Springfield, VA (US)

(73) Assignee: SAMSUNG ELECTRONICS CO., LTD., Suwon-si (KR)

(21) Appl. No.: 19/342,147

(22) Filed: Sep. 26, 2025

Related U.S. Application Data
(60) Provisional application No. 63/756,958, filed on Feb. 11, 2025.

(51) Int. Cl. H10D 84/85; H10D 84/01

(52) U.S. Cl. CPC H10D 84/856; H10D 84/0167; H10D 84/017; H10D 84/0186; H10D 84/0188; H10D 84/851

(57) ABSTRACT

A semiconductor device includes a 1^{st} transistor including a 1^{st} channel structure and a 1^{st} source/drain region connected to the 1^{st} channel structure in a 1^{st} direction intersecting a 2^{nd} direction, and a 2^{nd} transistor including a 2^{nd} channel structure and a 2^{nd} source/drain region connected to the 2^{nd} channel structure in the 1^{st} direction, wherein the 2^{nd} transistor is above the 1^{st} transistor in a 3^{rd} direction intersecting the 1^{st} direction and the 2^{nd} direction, and wherein a portion of the 1^{st} channel structure is not overlapped by the 2^{nd} channel structure and a portion of the 2^{nd} channel structure does not overlap the 1^{st} channel structure, in the 3^{rd} direction.

### CROSS-REFERENCE TO THE RELATED APPLICATION

This application is based on and claims priority from U.S. Provisional Application No. 63/756,958 filed on Feb. 11, 2025 in the U.S. Patent and Trademark Office, the disclosure of which is incorporated herein in its entirety by reference.

### BACKGROUND

### 1. Field

The disclosure relates to a semiconductor device having a Z-shaped multi-stack transistor structure.

### 2. Description of the Related Art

Increasing demand for high-performance, high-density semiconductor devices has introduced a nanosheet transistor characterized by multiple nanosheet layers bridging source/drain regions and a gate structure that wraps around or surrounds the nanosheet layers. These nanosheet layers serve as a channel structure for current flow between source/drain regions of the nanosheet transistor. Due to this structure, improved control of current flow through the nanosheet layers by the gate structure is enabled in addition to high device density in a semiconductor device including the nanosheet transistor. The nanosheet transistor is also referred to as various different names such as gate-all-around transistor, multi-bridge channel field-effect transistor (MBCFET), nanobeam transistor, nanoribbon transistor, superimposed channel device, etc.

Further, a multi-stack transistor structure or a three-dimensional-stacked transistor structure based on the nanosheet transistors has been introduced in response to increased demand for an integrated circuit having an even higher device density and performance. The multi-stack transistor structure may include a lower nanosheet transistor at a lower stack and an upper nanosheet transistor at an upper stack above the lower stack.

Moreover, a backside power distribution network (BSPDN) structure formed at a back side of a field-effect transistor structure such as a nanosheet transistor has been introduced to address a routing complexity and excessive IR drop at a front side of the field-effect transistor structure, thereby to achieve high power delivery performance, and further, to scale down a standard cell height. The BSPDN structure may include a backside metal line and/or a backside contact plug through which a positive or negative voltage may be supplied to a source/drain region of the field-effect transistor.

As the nanosheet transistor, the multi-stack transistor structure including the nanosheet transistors, and the BSPDN structure are widely adopted to form a semiconductor device, more diverse transistor structures are required to implement an optimized semiconductor device in terms of performance, power consumption, device density, etc.

Information disclosed in this Background section has already been known to the inventors before achieving the embodiments of the present application or is technical information acquired in the process of achieving the embodiments. Therefore, it may contain information that does not form the prior art that is already known to the public.

### SUMMARY

The disclosure provides a semiconductor device including one or more Z-shaped multi-stack transistor structure based on a channel spacer formed at a side of a lower channel stack and replaced by an outer spacer. The disclosure also provides that the semiconductor device including one or more Z-shaped multi-stack transistor structure may have interconnect structures at both a front side and a back side thereof.

According to one or more embodiments, there is provided a semiconductor device which may include a 1^{st} transistor including a 1^{st} channel structure and a 1^{st} source/drain region connected to the 1^{st} channel structure in a 1^{st} direction intersecting a 2^{nd} direction, and a 2^{nd} transistor including a 2^{nd} channel structure and a 2^{nd} source/drain region connected to the 2^{nd} channel structure in the 1^{st} direction, wherein the 2^{nd} transistor is above the 1^{st} transistor in a 3^{rd} direction intersecting the 1^{st} direction and the 2^{nd} direction, and wherein a portion of the 1^{st} channel structure is not overlapped by the 2^{nd} channel structure and a portion of the 2^{nd} channel structure does not overlap the 1^{st} channel structure, in the 3^{rd} direction.

According to one or more embodiments, there is provided a semiconductor device which may include a 1^{st} transistor including a 1^{st} channel structure and a 1^{st} source/drain region connected to the 1^{st} channel structure in a 1^{st} direction intersecting a 2^{nd} direction, and a 2^{nd} transistor including a 2^{nd} channel structure and a 2^{nd} source/drain region connected to the 2^{nd} channel structure in the 1^{st} direction, wherein the 2^{nd} transistor is above the 1^{st} transistor in a 3^{rd} direction intersecting the 1^{st} direction and the 2^{nd} direction, wherein the 1^{st} channel structure and the 2^{nd} channel structure have an equal channel width in the 2^{nd} direction intersecting the 1^{st} direction, and wherein the 2^{nd} channel structure is offset from the 1^{st} channel structure in the 2^{nd} direction.

According to one or more embodiments, there is provided a method of manufacturing a semiconductor device, the method including forming a 1^{st} channel structure extending in a 1^{st} direction intersecting a 2^{nd} direction, and forming a 2^{nd} channel structure extending in the 1^{st} direction above the 1^{st} channel structure in a 3^{rd} direction intersecting the 1^{st} direction and the 2^{nd} direction such that a portion of the 1^{st} channel structure is not overlapped by the 2^{nd} channel structure and a portion of the 2^{nd} channel structure does not overlap the 1^{st} channel structure, in the 3^{rd} direction.

### BRIEF DESCRIPTION OF THE DRAWINGS

Example embodiments of the disclosure will be more clearly understood from the following detailed description taken in conjunction with the accompanying drawings in which:

FIG. 1 illustrates a plan view of a semiconductor cell in which a semiconductor device including a multi-stack transistor structure is formed, according to one or more other embodiments;

FIGS. 2A-2C illustrate a semiconductor device including a multi-stack transistor structure formed in the semiconductor cell of FIG. 1, according to one or more embodiments;

FIGS. 3A-3C illustrate a semiconductor device including a multi-stack transistor structure formed in the semiconductor cell of FIG. 1 with contact structures different from those of the semiconductor device of FIGS. 2A-2C, according to one or more other embodiments;

FIG. 4 illustrates a semiconductor device including two multi-stack transistor structures formed in two semiconductor cells one of which is a flipped cell of the other, according to one or more embodiments;

FIG. 5 illustrates a semiconductor device including two multi-stack transistor structures formed in two semiconductor cells one of which has the same structure as the other, according to one or more embodiments;

FIGS. 6A-6T illustrate intermediate semiconductor devices obtained after respective steps of manufacturing a semiconductor device including multi-stack transistor structures, both Z-shaped and each being a flipped form of the other and including an outer spacer having a same material as inner spacers, according to one or more embodiments;

FIGS. 7A and 7B illustrate a flowchart of a method of manufacturing a semiconductor device including a multi-stack transistor structure having a Z-shape and including an outer spacer having a same material as inner spacers, according to one or more embodiments;

FIGS. 8A-8T illustrate intermediate semiconductor devices obtained after respective steps of manufacturing a semiconductor device including multi-stack transistor structures, both Z-shaped and each being a flipped form of the other and including an outer spacer having a same material as a middle isolation layer, according to one or more other embodiments;

FIGS. 9A and 9B illustrate a flowchart of a method of manufacturing a semiconductor device including a multi-stack transistor structure having a Z-shape and including an outer spacer having a same material as a middle isolation layer, according to one or more other embodiments; and

FIG. 10 is a schematic block diagram illustrating an electronic device including a semiconductor device in which one or more Z-shape multi-stack transistor structures are formed, according to one or more embodiments.

### DETAILED DESCRIPTION

All of the embodiments of the disclosure described herein are example embodiments, and thus, the disclosure is not limited thereto, and may be realized in various other forms. Each of the embodiments provided in the following description is not excluded from being associated with one or more features of another example or another embodiment also provided herein or not provided herein but consistent with the disclosure. For example, even if matters described in a specific example or embodiment are not described in a different example or embodiment thereto, the matters may be understood as being related to or combined with the different example or embodiment, unless otherwise mentioned in descriptions thereof. In addition, it should be understood that all descriptions of principles, aspects, examples, and embodiments of the disclosure are intended to encompass structural and functional equivalents thereof. In addition, these equivalents should be understood as including not only currently well-known equivalents but also equivalents to be developed in the future, that is, all devices invented to perform the same functions regardless of the structures thereof. For example, channel layers, sacrificial layers, and isolation layers described herein may take a different type or form as long as the disclosure can be applied thereto.

It will be understood that when an element, component, layer, pattern, structure, region, or so on (hereinafter collectively “element”) of a semiconductor device is referred to as being “over,” “above,” “on,” “below,” “under,” “beneath,” “connected to” or “coupled to” another element of the semiconductor device, it can be directly over, above, on, below, under, beneath, connected or coupled to the other element or an intervening element(s) may be present. In contrast, when an element of a semiconductor device is referred to as being “directly over,” “directly above,” “directly on,” “directly below,” “directly under,” “directly beneath,” “directly connected to” or “directly coupled to” another element of the semiconductor device, there are no intervening elements present. Like numerals refer to like elements throughout this disclosure.

Spatially relative terms, such as “over,” “above,” “on,” “upper,” “below,” “under,” “beneath,” “lower,” “left,” “right,” “lower-left,” “lower-right,” “upper-left,” “upper-right,” “central,” “middle,” and the like, may be used herein for ease of description to describe one element's relationship to another element(s) as illustrated in the figures. It will be understood that the spatially relative terms are intended to encompass different orientations of a semiconductor device in use or operation in addition to the orientation depicted in the figures. For example, if the semiconductor device in the figures is turned over, an element described as “below” or “beneath” another element would then be oriented “above” the other element. Thus, the term “below” can encompass both an orientation of above and below. The semiconductor device may be otherwise oriented (rotated 90 degrees or at other orientations) and the spatially relative descriptors used herein interpreted accordingly. As another example, when elements referred to as a “left” element and a “right” element may be a “right” element and a “left” element when a device or structure including these elements are differently oriented.

It will be understood that, although the terms “1^{st},” “2^{nd},” “3^{rd},” “4^{th},” “5th,” “6th,” etc. may be used herein to describe various elements, these elements should not be limited by these terms. These terms are only used to distinguish one element from another element. Thus, a 1^{st} element described in the descriptions of an embodiments could be termed a 2^{nd} element in the descriptions of another element or one or more claims, and vice versa without departing from the teachings of the disclosure.

As used herein, expressions such as “at least one of,” when preceding a list of elements, modify the entire list of elements and do not modify the individual elements of the list. For example, the expression, “at least one of a, b and c,” should be understood as including only a, only b, only c, both a and b, both a and c, both b and c, or all of a, b and c. The term “and/or” also includes any and all combinations of one or more of the associated listed items.

Herein, the terms of degree including “substantially” or “about” may be used. In one or more examples, when specifying that a parameter X may be substantially the same as parameter Y, the term “substantially” may be understood as X being within 10% of Y. In one or more examples, when specifying that a parameter is about X, the term “about” may be understood as being within 10% of X. Still, when a term “same” is used to compare parameters of two or more elements, the term may cover “substantially same” parameters.

It will be understood that, when the term “contact” is used to describe two metal elements, for example, a metal line and a via structure, a barrier metal layer such including titanium (Ti), tantalum (Ta), titanium nitride (TiN), tantalum nitride (TaN), tungsten nitride (WN), nickel nitride (NiN), cobalt nitride (CoN), or platinum nitride (PtN), not being limited thereto, may be formed therebetween. Further, it will be understood that, when a metal contact structure is described as being formed on or contact a surface of a source/drain region, a silicide layer including cobalt silicide (CoSi₂), nickel silicide (NiSi₂), titanium silicide (TiSi₂), or tungsten silicide (WSi₂), not being limited thereto, may be formed therebetween.

It will also be understood that, even if a certain step or operation of manufacturing an apparatus or structure is described later than another step or operation, the step or operation may be performed later than the other step or operation unless the other step or operation is described as being performed after the step or operation.

Many embodiments are described herein with reference to cross-sectional views that are schematic illustrations of the embodiments (and intermediate structures). As such, variations from the shapes of the illustrations as a result, for example, of manufacturing techniques and/or tolerances, are to be expected. Thus, the embodiments should not be construed as limited to the particular shapes of regions illustrated herein but are to include deviations in shapes that result, for example, from manufacturing. Various regions illustrated in the figures are schematic in nature and their shapes are not intended to illustrate the actual shape of a region of a device and are not intended to limit the scope of the disclosure. Further, in the drawings, the sizes and relative sizes of layers and regions may be exaggerated for clarity.

For the sake of brevity, conventional elements, structures or layers of semiconductor devices including a nanosheet transistor and materials forming the same may or may not be described in detail herein. For example, a certain isolation layer or structure of a semiconductor device and materials forming the same may be omitted herein when this layer or structure is not related to the novel features of the embodiments. Also, descriptions of materials forming well-known structural elements of a semiconductor device may be omitted herein when those materials are not relevant to the novel features of the embodiments. Herein, the term “isolation” and “insulation” pertains to electrical insulation or separation between structures, layers, components or regions in a corresponding device or structure.

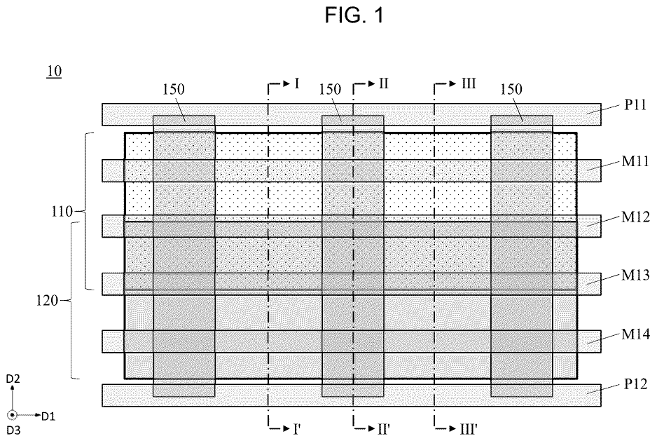

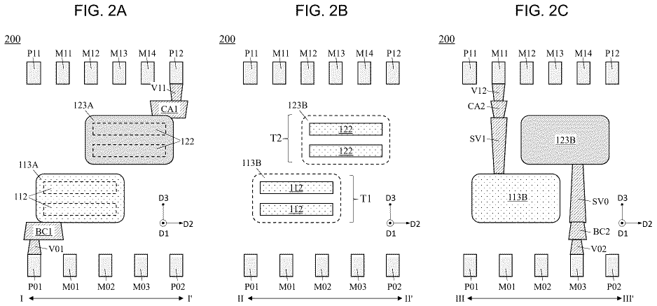

FIG. 1 illustrates a plan view of a semiconductor cell in which a semiconductor device including a multi-stack transistor structure is formed, according to one or more other embodiments. FIGS. 2A-2C illustrate the semiconductor device including the multi-stack transistor structure formed in the semiconductor cell of FIG. 1, according to one or more embodiments.

FIGS. 2A-2C are cross-section views of the semiconductor cell of FIG. 1 taken along lines I-I′, II-II′ and III-III′, respectively, shown in FIG. 1.

It is to be understood that FIGS. 1 and 2A-2C show only selected elements formed on a front side and a back side of the semiconductor cell and the semiconductor device such as front-end-of-line (FEOL) structures including channel structures, source/drain regions and/or gate structures and interconnect structures, and thus, some structural elements such as various isolation structures or layers are not shown for brevity purposes. It is also to be understood that FIG. 2A shows, in dashed lines, channel structures seen in the cross-section view, which is FIG. 2B, taken along the line II-II′, and FIG. 2B shows, in dashed lines, source/drain regions seen in the cross-section view, which is FIG. 2C, taken along the lines III-III′, to assist understanding of structural and positional relationships between the source/drain regions and the channel structures.

Referring to FIGS. 1 and 2A-2C, a semiconductor device 200 including a multi-stack transistor structure is formed in a semiconductor cell 10 based on a lower active pattern 110 and an upper active pattern 120. The upper active pattern 120 may be stacked on the lower active pattern 110 in a D3 direction, both active patterns 110 and 120 extending in a D1 direction. The lower active pattern 110 and the upper active pattern 120 may preferably, but not necessarily, have an equal width in a D2 direction. The two active patterns 110 and 120 may be horizontally offset from each other in the 2^{nd} direction. Due to this horizontal offset, a portion of the lower active pattern 110 may not be overlapped by the upper active pattern 120 in the D3 direction so that a top surface of the lower active pattern 110 is exposed upward in the D3 direction, and a portion of the upper active pattern 120 may not overlap the lower active pattern 110 in the D3 direction so that a portion of a bottom surface thereof is exposed downward in the D3 direction. The active patterns 110 and 120 may both be formed of at least silicon (Si).

The semiconductor cell 10 may also include a plurality of gate structures 150 arranged in the D1 direction and extending in the D2 direction across the active patterns 110 and 120. The gate structures 150 may include a gate electrode formed of a metal such as tungsten (W), copper (Cu), aluminum (Al), cobalt (Co), etc., or an alloy thereof, not being limited thereto.

A 1^{st} frontside power rail P11 and a 2^{nd} frontside power rail P12 may be formed on the front side of the semiconductor cell 10, at two borders of the semiconductor cell 10 opposite to each other in the D2 direction. These two frontside power rails P11 and P12 may extend in the D1 direction along the cell borders and may be disposed above the multi-stack transistor structure in the D3 direction. The 1^{st} frontside power rail P11 may be connected to a negative voltage source or ground, and the 2^{nd} frontside power rail P12 may be connected to a positive voltage source. However, according to one or more other embodiments, the 1^{st} frontside power rail P11 may be connected to the positive voltage source, and the 2^{nd} frontside power rail P12 may be connected to the negative voltage source or ground. Between the two frontside power rails P11 and P12 at the same level in the D3 direction may be formed 1^{st} to 4^{th} frontside metal lines M11-M14 extending in the D1 direction and arranged in the D2 direction at a predetermined metal pitch.

Although not shown in FIG. 1 for brevity purposes, a 1^{st} backside power rail P01 and a 2^{nd} backside power rail P02 may be formed on the back side of the semiconductor cell 10, at the two borders of the semiconductor cell 10, as shown in FIGS. 1B-1D. These two backside power rails P01 and P02 may extend in the D1 direction and be disposed below the multi-stack transistor structure in the D3 direction. The 1^{st} backside power rail P01 may be connected to the negative voltage source or ground, and the 2^{nd} backside power rail P02 may be connected to the positive voltage source. However, according to one or more other embodiments, the 1^{st} backside power rail P01 may be connected to the positive voltage source, and the 2^{nd} backside power rail P02 may be connected to the negative voltage source or ground. Between the two backside power rails P01 and P02 at the same level in the D3 direction may be formed 1^{st} to 3^{rd} backside metal lines M01-M03 extending in the D1 direction and arranged in the D2 direction at a predetermined metal pitch. The power rails P01, P02, P11 and P12 and the metal lines M01-M03 and M11-M14 may each be formed of a metal such as Cu, W, aluminum (Al), ruthenium (Ru), molybdenum (Mo), or an alloy thereof, not being limited thereto.

The multi-stack transistor structure forming the semiconductor device 200 in the semiconductor cell 10 may include a lower transistor T1 and an upper transistor T2 stacked above the lower transistor T2 in the D3 direction. The lower transistor T1 may include a plurality of lower channel layers 112 as a lower channel structure, a gate structure 150 (FIG. 1) on or surrounding the lower channel layers 112, and a lower source/drain regions 113A and 113B formed on at both ends of the lower channel layers 112. Similarly, the upper transistor T2 may include a plurality of upper channel layers 122 as an upper channel structure, the gate structure 150 (FIG. 1) also on or surrounding the upper channel layers 122, and upper source/drain regions 123A and 123B formed on at both ends of the upper channel layers 122. Thus, each of the lower transistor and the upper transistor may take a form of a nanosheet transistor.

The channel layers 112 and 122 may be epitaxially grown from a Si-based substrate, and thus, may include Si. Each of the source/drain regions 113A 113B, 123A and 123B may be formed of Si or silicon germanium (SiGe). For example, when the lower transistor T1 is of p-type, the lower source/drain regions 113A and 113B may be formed of SiGe doped with p-type impurities (e.g., boron (B), gallium (Ga), or indium (In)). In contrast, when the lower transistor T1 is of n-type, the lower source/drain regions 113A and 113B may be formed of Si doped with n-type impurities (e.g., phosphorus (P), arsenic (As), or antimony (Sb)).

The lower channel layers 112 and the lower source/drain regions 113A and 113B may form or correspond to the lower active pattern 110, and the upper channel layers 122 and the upper source/drain regions 123A and 123B may form or correspond to the upper active pattern 120.

In a case where the lower active pattern 110 and the upper active pattern 120 have an equal width in the D2 direction as described above, the lower channel layers 112 and the upper channel layers 122 may each have an equal width in the D2 direction. Accordingly, the lower source/drain regions 113A and 113B epitaxially grown from the lower channel layers 112 may each have a width equal to a width of each of the upper source/drain regions 123A and 123B epitaxially grown from the upper channel layers 122. The channel layers 112 and 122 may have an equal length or different lengths in the D1 direction. The source/drain regions 113A, 113B, 123A and 123B may also have an equal length or different lengths in the D1 direction.

The lower source/drain region 113A may be connected to the 1^{st} backside power rail P01 through a 1^{st} backside contact plug BC1 and a 1^{st} backside via V01. In contrast, the upper source/drain region 123A may be connected to the 2^{nd} frontside power rail P12 through a 1^{st} frontside contact plug CA1 and a 1^{st} frontside via V11. As the lower source/drain region 113A and the upper source/drain region 123A are respectively connected to voltage sources through the closest 1^{st} backside power rail P01 and 2^{nd} frontside power rail P12, an IR drop may be minimized to improve power performance of the semiconductor device 200.

In the meantime, as the lower active pattern 110 and the upper active pattern 120 are offset from each other in the D2 direction as shown in FIG. 1, the lower channel layers 112 may be offset from the upper channel layers 122 or vice versa in the D2 direction. Accordingly, the lower source/drain regions 113A and 113B may be offset from the upper source/drain regions 123A and 123B, respectively, or vice versa in the D2 direction. Thus, the multi-stack transistor structure formed in the semiconductor device 200 may be referred to as a Z-shaped multi-stack transistor structure.

Due to the aforementioned Z-shaped multi-stack transistor structure, a portion of a top surface of the lower source/drain region 113B may be exposed upward in the D3 direction, and a portion of a bottom surface of the upper source/drain region 123B may be exposed downward in the D3 direction. Thus, even in the multi-stack transistor structure, the top surface of the lower source/drain region 113B may be connected to the 1^{st} frontside metal line M11 through a 2^{nd} frontside via SV1, a 2^{nd} frontside contact plug CA2 and a 3^{rd} frontside via V12 for signal routing in an integrated circuit including the semiconductor device 200, thereby achieving increased device density. Similarly, the bottom surface of the upper source/drain regions 123B may be connected to the 3^{rd} backside metal line M 03 through a 2^{nd} backside via SV 0, a 2^{nd} backside contact plug BC2 and a 3^{rd} backside via V02 for signal routing purposes, thereby achieving additionally increased device density. The contact structures BC1, BC2, CA1, CA2, V01, V02, V11, V12, SV0 and SV1 may each be formed of a metal such as Cu, Al, W, Ru, Mo, or an alloy thereof, not being limited thereto.

In the above embodiments of the semiconductor device 200, the lower source/drain region 113A is connected to a voltage source through the 1^{st} backside power rail P01. However, as the semiconductor cell 10 is structured such that the 1^{st} to 3^{rd} backside metal lines M01-M03 are formed between the backside power rails P01 and P02, the lower source/drain region 113A may be formed to be connected to one of these backside metal line M 01-M03 for signal routing purposes instead of being connected to the 1^{st} backside power rail P01. The following embodiments present a different device structure that can be formed in the semiconductor cell 10 of FIG. 1.

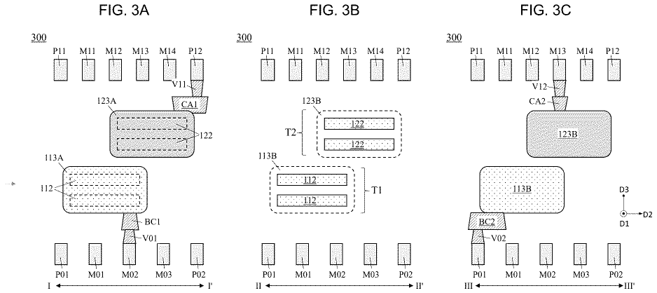

FIGS. 3A-3C illustrate a semiconductor device including a multi-stack transistor structure formed in the semiconductor cell of FIG. 1 with contact structures different from those of the semiconductor device of FIGS. 2A-2C, according to one or more other embodiments. FIGS. 3A-3C are cross-section views of the semiconductor cell 10 of FIG. 1 taken along lines I-I′, II-II′ and III-III′, respectively, shown in FIG. 1 when a semiconductor device including a multi-stack transistor structure is formed therein.

Referring to FIGS. 3A-3C along with FIG. 1, a semiconductor device 300 including a multi-stack transistor structure is formed in the semiconductor cell 10 based on the lower active pattern 110 and the upper active pattern 120. The semiconductor device 300 has the same structural elements forming the semiconductor device 200 of FIGS. 2A-2C except contact structures such as frontside contact plugs, frontside vias, backside contact plugs, and backside vias. Thus, only different aspects of the semiconductor device 300 may be described herebelow while duplicate descriptions thereof may be omitted.

As the semiconductor cell 10 provides not only the backside power rails P01 and P02 but the 1^{st} to 3^{rd} backside metal lines M01-M03, the semiconductor device 300 may be designed and structured such that the lower source/drain region 113A is connected to a backside metal line such as the 2^{nd} backside metal line M 02 through a 1^{st} backside contact plug BC1 and a 1^{st} backside via V01 for signal routing purposes. In contrast, the lower source/drain region 113B may be connected to a backside power rail such as the 1^{st} backside power rail P01 through a 2^{nd} backside contact plug BC2 and a 2^{nd} backside via V02. Further, while the semiconductor device 200 of FIGS. 2A-2C is structured such that the upper source/drain region 123A is connected to the 2^{nd} frontside power rail P12 through the 1^{st} frontside contact plug CA1 and the 1^{st} frontside via V11, the upper source/drain region 123B may be connected to the 3^{rd} frontside metal line M13 through a 2^{nd} frontside contact plug CA2 and a 2^{nd} frontside via V12 for signal routing.

Thus, each of the semiconductor devices 200 and 300 formed of a multi-stack transistor structure may be characterized in that the lower source/drain regions 113A and 113B and the upper source/drain regions 123A and 123B are offset in the D2 direction to form a Z-shaped multi-stack transistor structure while power rails are formed on both the front side and the back side with corresponding metal lines therebetween, thereby achieving power performance improvement and increased device density. Accordingly, the semiconductor devices 200 and 300 may provide freedom of circuit design and cell design while achieving improved power performance and increased device density, and further, avoiding congestion of contact structures on the front side and the back side of the semiconductor devices 200 and 300.

In the meantime, the semiconductor cell 10 of FIG. 1 including the Z-shaped multi-stack transistor structure may be flipped or mirrored to form another semiconductor cell including a Z-shaped structure as described in the following embodiments.

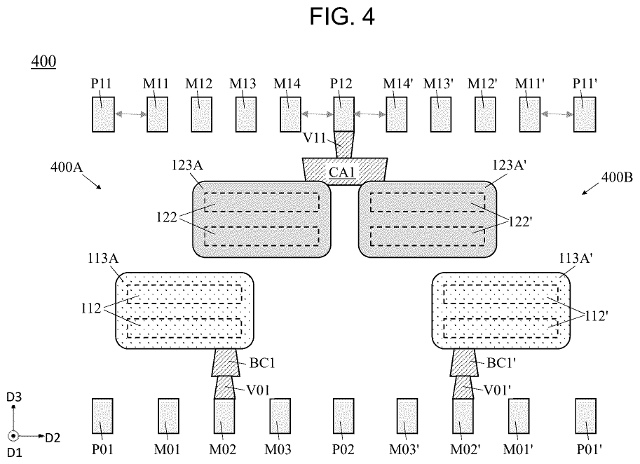

FIG. 4 illustrates a semiconductor device including two multi-stack transistor structures formed in two semiconductor cells one of which is a flipped cell of the other, according to one or more embodiments.

Referring to FIG. 4, a semiconductor device 400 includes a 1^{st} multi-stack transistor structure 400A formed in a semiconductor cell and a 2^{nd} multi-stack transistor structure 400B formed in another semiconductor cell. The semiconductor cell including the 1^{st} multi-stack transistor structure 400A may be the same as the semiconductor cell 10 of FIG. 1, and the semiconductor cell including the 2^{nd} multi-stack transistor structure 400B may be formed by flipping or mirroring the semiconductor cell including the 1^{st} multi-stack transistor structure 400A in the D2 direction. Thus, except that the 2^{nd} multi-stack transistor structure 400B is a flipped form of the 1^{st} multi-stack transistor structure 400A in the 2^{nd} direction, the 2^{nd} multi-stack transistor structure 400B may be the same as the 1^{st} multi-stack transistor structure 400A.

For example, the 1^{st} multi-stack transistor structure 400A may include a lower transistor formed of a plurality of lower channel layers 112 with a lower source/drain region 113A thereon and an upper transistor formed of a plurality of upper channel layers 122 with an upper source/drain region 123A thereon. The 1^{st} multi-stack transistor structure 400A may be the same as the multi-stack transistor structure formed in the semiconductor cell 10 as shown in FIGS. 1, 2A-2C and 3A-3C, and thus, duplicate descriptions thereof may be omitted herein. Further, the 2^{nd} multi-stack transistor structure 400B may include a lower transistor formed of a plurality of lower channel layers 112′ with a lower source/drain region 113A′ thereon and an upper transistor formed of a plurality of upper channel layers 122′ with an upper source/drain region 123A′. The lower transistor and the upper transistor of the 2^{nd} multi-stack transistor structure 400B may be the same as those of the 1^{st} multi-stack transistor structure 400A except for their flipped form, duplicate descriptions thereof may also be omitted herein.

An interconnect structures for the 2^{nd} multi-stack transistor structure 400B may also be a flipped form of an interconnect structure for the 2^{nd} multi-stack transistor structure 400B. For example, the 2^{nd} multi-stack transistor structure 400B may have thereabove and therebelow a 1^{st} frontside power rails P11′, 1^{st} to 4^{th} frontside metal lines M11′-M14′, a 1^{st} backside power rail P01′, and 1^{st} to 3^{rd} backside metal lines M01′-M03′ which are flipped forms of a 1^{st} frontside power rails P11, 1^{st} to 4^{th} frontside metal lines M11-M14, a 1^{st} backside power rail P01, and 1^{st} to 3^{rd} backside metal lines M01-M03 formed above and below the 1^{st} multi-stack transistor structure 400A. Further, the 2^{nd} multi-stack transistor structure 400B may have therebelow a 1^{st} backside contact plug BC1′ and a 1^{st} backside via V01′ which are flipped forms of a 1^{st} backside contact plug BC1 and a 1^{st} backside via V01 of the 1^{st} multi-stack transistor structure 400A, respectively.

However, a 2^{nd} frontside power rail P12 and a 2^{nd} backside power rail P02 may be shared by the two multi-stack transistor structure 400A and 400B. Moreover, a common 1^{st} frontside contact plug CA1 with a common 1^{st} frontside via V11 thereon may be formed between the two multi-stack transistor structures 400A and 400B to connect the two upper source/drain regions 123 and 123′ to the 2^{nd} frontside power rail P12 therethrough. The aforementioned power rail and contact structure sharing may be enabled as the two upper source/drain regions 123 and 123′ can be disposed next to each other as the two multi-stack transistor structures 400A and 400B are both Z-shaped with each being a flipped form of the other.

In the meantime, another semiconductor cell having the same structure as the semiconductor cell 10 shown in FIG. 1 including the Z-shaped multi-stack transistor structure may be placed next to the semiconductor cell 10 as described in the following embodiments.

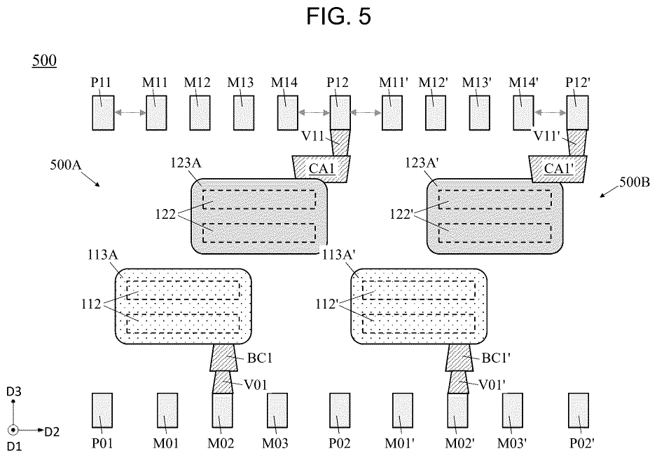

FIG. 5 illustrates a semiconductor device including two multi-stack transistor structures formed in two semiconductor cells one of which has the same structure as the other, according to one or more embodiments;

Referring to FIG. 5, a semiconductor device 500 includes a 1^{st} multi-stack transistor structure 500A formed in a semiconductor cell and a 2^{nd} multi-stack transistor structure 500B formed in another semiconductor cell which has the same structure as the semiconductor cell including the 1^{st} multi-stack transistor structure 500A.

For example, the 1^{st} multi-stack transistor structure 500A may include a lower transistor formed of a plurality of lower channel layers 112 with a lower source/drain region 113A thereon and an upper transistor formed of a plurality of upper channel layers 122 with an upper source/drain region 123A thereon. The 1^{st} multi-stack transistor structure 500A may be the same as the multi-stack transistor structure formed in the semiconductor cell 10 as shown in FIGS. 1, 2A-2C and 3A-3C, and thus, duplicate descriptions thereof may be omitted herein. Further, the 2^{nd} multi-stack transistor structure 500B may include a lower transistor formed of a plurality of lower channel layers 112′ with a lower source/drain region 113A′ thereon and an upper transistor formed of a plurality of upper channel layers 122′ with an upper source/drain region 123A′ thereon. The lower transistor and the upper transistor of the 2^{nd} multi-stack transistor structure 500B may be the same as those of the 1^{st} multi-stack transistor structure 500A, and thus, duplicate descriptions thereof may be omitted herein.

Interconnect structures for the 2^{nd} multi-stack transistor structure 500B may also be the same as an interconnect structure for the 1^{st} multi-stack transistor structure 500A. For example, the 2^{nd} multi-stack transistor structure 500B may have thereabove and therebelow 1^{st} to 4^{th} frontside metal lines M11′-M14′, a 2^{nd} frontside power rail P12′, 1^{st} to 3^{rd} backside metal lines M01′-M03′, a 2^{nd} backside power rail P02′, a 1^{st} frontside contact plug CA1′, and a 1^{st} frontside via V11′ which are respectively the same as 1^{st} to 4^{th} frontside metal lines M11-M14, a 2^{nd} frontside power rail P12, 1^{st} to 3^{rd} backside metal lines M01-M03, a 2^{nd} backside power rail P02, a 1^{st} frontside contact plug CA1, and a 1^{st} frontside via V11 formed above and below the 1^{st} multi-stack transistor structure 500A. Further, the 2^{nd} multi-stack transistor structure 500B may have therebelow a 1^{st} backside contact plug BC1′ and a 1^{st} backside via V01′ which are respectively the same as a 1^{st} backside contact plug BC1 and a 1^{st} backside via V01 of the 1^{st} multi-stack transistor structure 500A, respectively.

However, the 2^{nd} frontside power rail P12 and the 2^{nd} backside power rail P02 of the 1^{st} multi-stack transistor structure 500A may be shared by the 2^{nd} multi-stack transistor structure 500B although only the upper source/drain region 123A of the 1^{st} multi-stack transistor structure 500A may be connected to the 2^{nd} frontside power rail P12 while the upper source/drain region 123A′ of the 2^{nd} multi-stack transistor 500B is connected to 2^{nd} frontside power rail P12′.

The aforementioned sequential device structure formed by the two same multi-stack transistor structures 500A and 500B having the Z-shape may achieve a less risk of short circuit between a frontside contact structure of the 1^{st} multi-stack transistor structure 500A formed of the 1^{st} frontside contact plug CA1 and the 1^{st} frontside via V11 and a frontside contact structure of the 2^{nd} multi-stack transistor structure 500B formed of the 1^{st} frontside contact plug CA1′ and the 1^{st} frontside via V11′. This is because when the two Z-shaped multi-stack transistor structures 500A and 500B are sequentially disposed or placed as shown in FIG. 5, a sufficient distance between the 2^{nd} upper source/drain regions 123A and 123A′ can be obtained.

Herebelow, a method of manufacturing a semiconductor device including two multi-stack transistor structures formed in two semiconductor cells one of which is a flipped cell of the other.

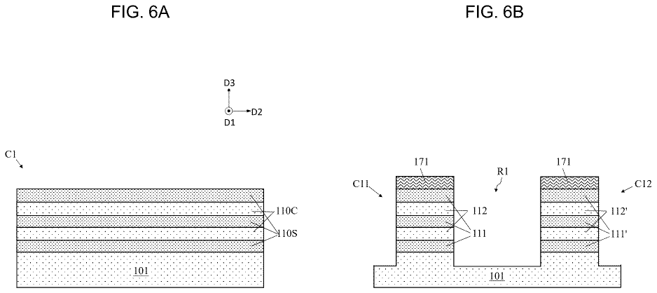

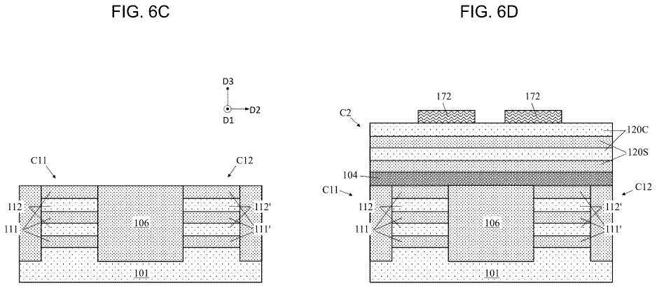

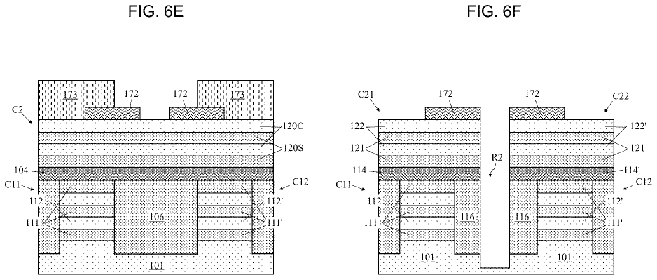

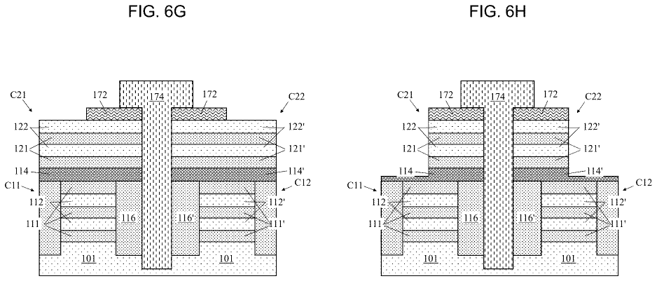

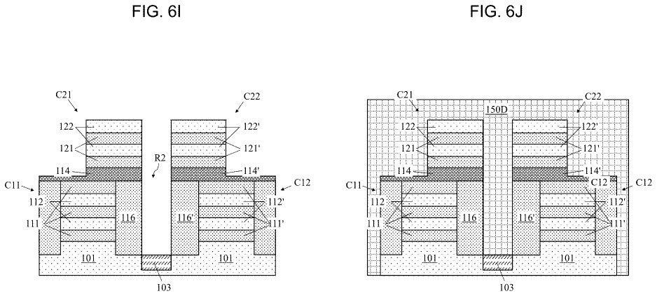

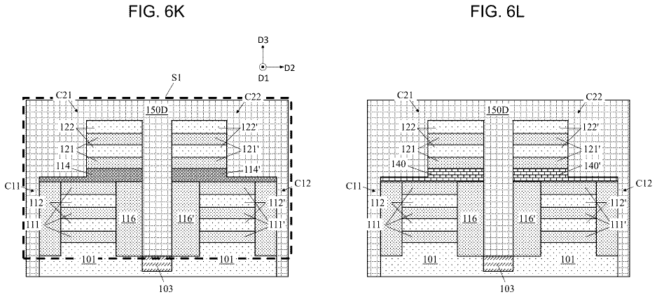

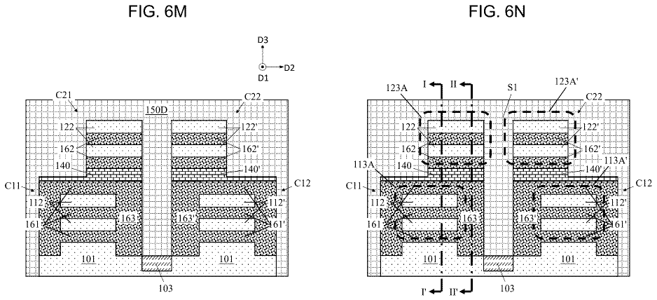

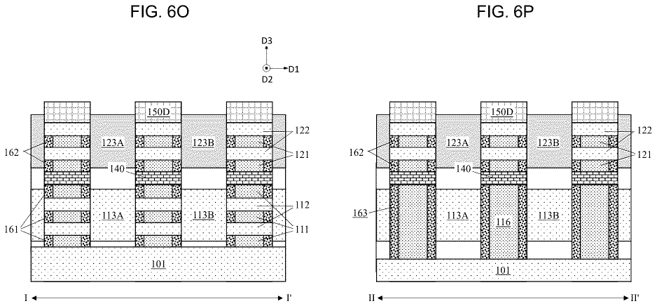

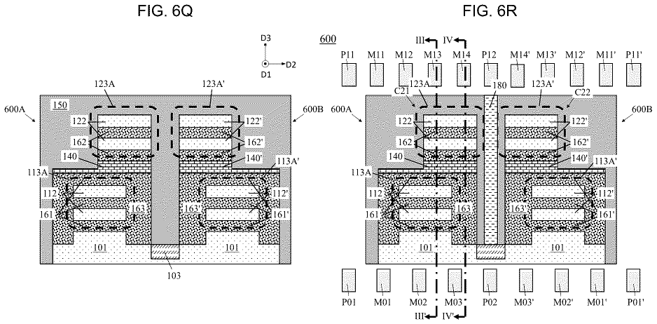

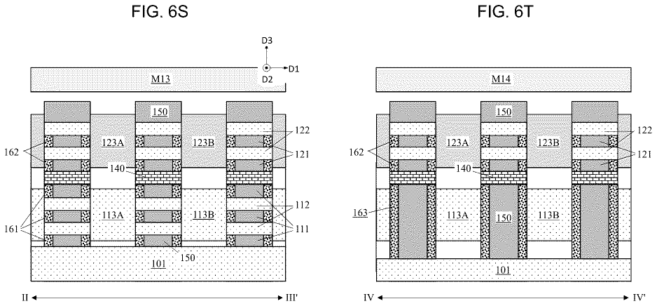

FIGS. 6A-6T illustrate intermediate semiconductor devices obtained after respective steps of manufacturing a semiconductor device including multi-stack transistor structures, both Z-shaped and each being a flipped form of the other and including an outer spacer having a same material as inner spacers, according to one or more embodiments.

The semiconductor device manufactured through the steps described herebelow may correspond to or may be the same as the semiconductor device 400 shown in FIG. 4. Thus, duplicate descriptions about structures and materials thereof may be omitted and the same reference numerals and characters may be used in FIGS. 6A-6T and the descriptions thereof. It is to be understood here that FIGS. 6A-6T are cross-section views of the intermediate semiconductor devices showing channel structures such as FIGS. 2B and 3B.

Referring to FIG. 6A, an initial channel stack C1 may be formed by growing a plurality of lower semiconductor layers on a substrate 101.

The lower semiconductor layers, also referred to as lower nanosheet layers, may be epitaxially grown from the substrate 101 in an alternating manner to form a plurality of lower sacrificial layers 110S and a plurality of lower channel layers 110C interposed therebetween. The substrate 101 and the lower channel layers 110C may be formed of silicon (Si), and the lower sacrificial layers 110S may be formed of silicon germanium (SiGe).

Referring to FIG. 6B, the initial lower channel stack C1 may be patterned based on 1^{st} hard mask patterns 171 to form a lower-left channel stack C11 and a lower-right channel stack C12.

The initial lower channel stack C1 may be patterned through, for example, dry etching such as reactive ion etching (RIE) based on the 1^{st} hard mask patterns 171 formed on a top surface thereof to form the lower-left channel stack C11 and the lower-right channel stack C12 spaced apart from each other by a 1^{st} recess R1 therebetween. The lower-left channel stack C11 may be formed of lower-left sacrificial layers 111 and lower-left channel layers 112 interposed therebetween, and the lower-right channel stack C12 may be formed of lower-right sacrificial layers 111′ and lower-right channel layers 112′ interposed therebetween. A width of the lower-left channel stack C11 may be equal to or different from a width of the lower-right channel stack C12 in the D2 direction.

The patterning operation in this step may also be performed such that an initial top surface of the substrate 101 below the lowermost sacrificial layer 110S is recessed to expose a recessed top surface of the substrate 101 through the 1^{st} recess R1 so that a spacer structure may be formed between the two lower channel stacks C11 and C12 on the recessed top surface of the substrate 101 in a next step (FIG. 6C).

The 1^{st} hard mask patterns 171 used for the patterning operation in this step may be formed of silicon nitride (Si₃N₄) or silicon carbide (SiC), not being limited thereto.

Referring to FIG. 6C, a spacer structure 106 formed of SiGe may fill in the 1^{st} recess R1.

The spacer structure 106 formed of SiGe may be epitaxially grown from at least one of the lower channel stacks C11 and C12 and the substrate 101 to fill out the 1^{st} recess R1 on the substrate 101, followed by removal of the 1^{st} hard mask patterns 171 and planarization so that a top surface of the spacer structure 106 may be aligned or coplanar with a top surface of each of the uppermost lower sacrificial layers 111 and 111′ in the D2 direction. Here, the spacer structure 106 may be epitaxially grown such that Ge concentration in SiGe forming the spacer structure 106 may be equal to Ge concentration in SiGe forming the lower sacrificial layers 111 and 111′.

In the 1^{st} recess R1, the spacer structure 106 may be formed to contact and extend along side surfaces of the lower-left channel stack C11 and the lower-right channel stack C12 in the D1 direction such that a length of the spacer structure 106 may be equal to lengths of the lower-left channel stack C11 and the lower-right channel stack C12 in the D1 direction.

Referring to FIG. 6D, an initial middle sacrificial layer 104 may be formed on the top surfaces of the spacer structure 106, the uppermost sacrificial layer 111 of the lower-left channel stack C11 and the uppermost sacrificial layer 111′ of the lower-right channel stack C12, and an initial upper channel stack C2 may be formed by growing a plurality of upper semiconductor layers on the initial middle sacrificial layer 104.

The initial middle sacrificial layer 104 may be formed of SiGe with a higher Ge concentration than the sacrificial layers 111 and 111′ and the spacer structure 106. For example, the Ge concentration in the initial middle sacrificial layer 104 may be 40-45%, and the Ge concentration in the sacrificial layers 111 and 111′ and the spacer structure 106 may be 25-30% so that these SiGe layers may have etch selectivity against each other.

To form the initial upper channel stack C2, a plurality of upper semiconductor layers, also referred to as upper nanosheet layers, may be epitaxially grown from the initial middle sacrificial layer 104 in an alternating manner to form a plurality of upper sacrificial layers 120S and a plurality of upper channel layers 120C. The upper channel layers 120C may be formed of Si and the upper sacrificial layers 120S are formed of SiGe. The upper sacrificial layers 120S of SiGe may also have a lower Ge concentration, for example, 25-30%.

Subsequently, 2^{nd} hard mask patterns 172 may be formed on the uppermost upper channel layer 120C of the initial upper channel stack C2 at positions below which an upper-left channel stack and an upper-right channel stack are to be formed with respective offsets with respect to the lower-left channel stack C11 and the lower-right channel stack C12, respectively, in a later step (FIG. 6H).

The 2^{nd} hard mask patterns 172 may also be formed on the uppermost upper channel layer 120C at the positions which render a pair of the upper-left channel stack and the lower-left channel stack C11 take a flipped form of a pair of the upper-right channel stack and the lower-right channel stack C12, and vice versa, in the D2 direction. Moreover, the 2^{nd} hard mask patterns 172 may be formed such that widths thereof are equal to each other and equal to widths of the lower channel stacks C11 and C12 in the D2 direction, but not being limited thereto. The 2^{nd} hard mask patterns 172 may also be formed of silicon nitride (Si3N 4) or silicon carbide (SiC), not being limited thereto.

Here, lengths of the initial upper channel stack C2, the initial middle sacrificial layer 104, the 2^{nd} hard mask patterns 172 may be equal to the lengths of the lower channel stacks C11, C12 and the spacer structure 106 in the D1 direction.

Referring to FIGS. 6E, 3^{rd} hard mask patterns 173 may be formed on a top surface of the intermediate semiconductor device obtained in the previous step.

The 3^{rd} hard mask patterns 173 may be formed on at least a portion of a top surface of each of the 2^{nd} hard mask patterns 172 and a top surface of the uppermost upper channel layer 112C except for a portion between the two 2^{nd} hard mask patterns 172. The 3^{rd} hard mask patterns 173 may be formed of spin-on-carbide (SoC) or spin-on-glass (SoG), not being limited thereto.

Referring to FIG. 6F, the intermediate semiconductor device obtained in the previous step may be patterned based on the 2^{nd} hard mask patterns 172 and the 3^{rd} hard mask patterns 173 to form a 2^{nd} recess R2 dividing the intermediate semiconductor device into two intermediate semiconductor devices.

The 2^{nd} recess R2 may be formed through, for example, dry etching such as RIE, based on the 2^{nd} hard mask patterns 172 and the 3^{rd} hard mask patterns 173 to divide the initial upper channel stack C2 into an upper-left channel stack C21 and an upper-right channel stack C22. The upper-left channel stack C21 may be formed of a plurality of upper-left sacrificial layers 121 and upper-left channel layers 122, and the upper-right channel stack C22 may be formed of a plurality of upper-right sacrificial layers 121′ and upper-right channel layers 122′.

The 2^{nd} recess R2 may also divide the initial middle sacrificial layer 104 into a left middle sacrificial layer 114 and a right middle sacrificial layer 114′, and divide the spacer structure 106 formed between the lower-left channel stack C11 and the lower-right channel stack C12 into a left channel spacer 116 and a right channel spacer 116′. Further, the 2^{nd} recess R2 may penetrate into the substrate 101 to further recess the substrate 101.

After forming the 2^{nd} recess R2, the 3^{rd} hard mask patterns 173 may be selectively removed against the 2^{nd} hard mask patterns 172 and the uppermost upper channel layer 120C.

Referring to FIGS. 6G and 6H, a 4^{th} hard mask pattern 174 may fill out the 2^{nd} recess R2, and, based on the 4^{th} hard mask pattern 174 and the 2^{nd} hard mask patterns 172, the upper-left channel stack C21 and the upper-right channel stack C22 may be patterned.

In a case where the 2^{nd} hard mask patterns 172 have equal widths in the D2 direction, the upper-left channel stack C21, the upper-right channel stack C22, the lower-left channel stack C11, and the lower-right channel stack C12 may have an equal width in the D2 direction. Further, due to the positions of the 2^{nd} hard mask patterns 172 on the uppermost upper-left channel layer 122 and the uppermost upper-right channel layer 122′, respectively, the upper-left channel stack C21 may be offset to the right with respect to the lower-left channel stack C11, and the upper-right channel stack C22 may be offset to the left with respect to the lower-right channel stack C12, by the same distance. Thus, the pair of the upper-left channel stack C21 and the lower-left channel stack C11 may take a flipped form of the pair of the upper-right channel stack C22 and the lower-right channel stack C12, and vice versa, with respect to the 4^{th} hard mask pattern 174.

Due to the aforementioned channel stack offset, the left channel spacer 116 on a right side of the lower-left channel stack C11 may be formed below and overlapped by a right portion of the upper-left channel stack C21 in the D3 direction. Similarly, the right channel spacer 116′ on a left side of the lower-right channel stack C12 may be formed below and overlapped by a left portion of the upper-right channel stack C22 in the D3 direction.

The 4^{th} hard mask pattern 174 may be formed of SoC or SoG like the 3^{rd} hard mask patterns 173, and the patterning operation in this step may be performed through, for example, dry etching such as RIE, not being limited thereto.

Referring to FIG. 6I, the 4^{th} hard mask pattern 174 and the 2^{nd} hard mask patterns 172 may be removed and the 2^{nd} recess R2 is reopened, followed by formation of a shallow trench isolation (STI) structure 103 at a lower portion of the 2^{nd} recess R2.

The 4^{th} hard mask pattern 174 and the 2^{nd} hard mask patterns 172 may be removed through, for example, plasma ashing or wet cleaning which may also be used to remove the 3^{rd} hard mask patterns 173 in the previous step of FIG. 6F. Further, the STI structure 103 may be formed in the recess in the substrate 101, which is formed in the previous step of FIG. 6F through, for example, chemical vapor deposition (CVD) of a low-k dielectric material such as silicon oxide (SiO₂), not being limited thereto.

Referring to FIG. 6J, a dummy gate structure 150D may be formed to surround the intermediate semiconductor device obtained in the previous step.

The dummy gate structure 150D may be formed through, for example, depositing sacrificial polysilicon by CVD to surround the pair of the lower-left channel stack C11 and the upper-left channel stack C21 and the pair of the lower-right channel stack C12 and the upper-right channel stack C22.

Referring to FIG. 6K, the intermediate semiconductor device obtained in the previous step may be patterned to form a plurality of spaces S1 where left source/drain regions and right source/drain regions are to be formed in a later step (FIG. 6N).

In this step, dry etching such as RIE may be performed on the channel stacks C11, C21, C12 and C22 extending in the D1 direction with the dummy gate structure 150D thereon to form the spaces S1 for the left source/drain regions and the right source/drain regions. The positions of the spaces S1, one of which is indicated by a dashed rectangle in FIG. 6K, corresponds to a position between two adjacent gate structures 150 shown in FIG. 1. Thus, a space S1 among the spaces S1 may be formed between a set of patterned channel stacks C11, C21, C12 and C22 with a patterned dummy gate structure 150D and an adjacent set of patterned channel stacks C11, C21, C12 and C22 with an adjacent patterned dummy gate structure 150D in the D1 direction.

As the spaces S1 are formed to divide the channel stacks C11, C21, C12 and C22 with a patterned dummy gate structure 150D in the Di direction, the channel spacers 116 and 116′ and the middle sacrificial layers 114 and 114′ may also be patterned to have equal lengths as a set of patterned channel stacks C11, C21, C12 and C22 with a patterned dummy gate structure 150D in the D1 direction.

Thus, the channel stacks C11, C12, C21 and C22 with the middle sacrificial layers 114 and 114′ surrounded by the dummy gate structure 150D shown in FIG. 6K and thereafter are a set of patterned channel stacks C11, C21, C12 and C22 with patterned middle sacrificial layers 114 and 114′ surrounded by a patterned dummy gate structure 150D having equal lengths in the D1 direction.

Referring to FIG. 6L, the left middle sacrificial layer 114 and the right middle sacrificial layer 114′ may be removed and replaced by a left middle isolation layer 140 and a right middle isolation layer 140′, respectively, through the spaces S1 formed in the previous step (FIG. 6K).

The left middle sacrificial layer 114 and the right middle sacrificial layer 114′ formed of SiGe with a higher Ge concentration may be removed through, for example, selective wet etching or dry etching against the sacrificial layers 111, 111′, 121 and 121′ and the channel spacers 116 and 116′ formed of SiGe but with a lower Ge concentration and the channel layers 112, 112′, 122 and 122′ formed of Si. For wet etching, hydrofluoric acid may be used as etchant, and for dry etching, fluorine-based plasma may be used as etchant.

Subsequently, the left middle isolation layer 140 and the right middle isolation layer 140′ may be formed in spaces provided by the removal of the left middle sacrificial layer 114 and the right middle sacrificial layer 114′, respectively. The middle isolation layers 140 and 140′ may each be formed through, for example, CVD or plasma-enhanced CVD (PECVD), atomic layer deposition (ALD), etc. of an isolation material such as silicon nitride (e.g., SiN or Si₃N₄), SiBCN, SiCN, SiOC, SiON, SiBC, SiBN or SiOCN, a combination thereof, not being limited thereto.

Referring to FIG. 6M, lower-left inner spacers 161, upper-left inner spacers 162, lower-right inner spacers 161′ and upper-right inner spacers 162′, a left outer spacer 163, and a right outer spacer 163′ may be formed in the intermediate semiconductor device obtained in the previous step.

The inner spacers 161, 162, 161′ and 162′ may be formed in spaces provided by removing portions of the sacrificial layers 111, 111, 121 and 121′ of SiGe from D1-direction side surfaces thereof. The outer spacers 163 and 163′ may be formed in spaces provided by removing portions of the channel spacers 116 and 116′ of SiGe also from D1-direction side surfaces thereof. Thus, the inner spacers 161, 162, 161′ and 162′ may be on and directly contact the sacrificial layers 111, 111, 121 and 121′, respectively, in the D1 direction, and the outer spacers 163 and 163′ may be on and directly contact the channel spacers 116 and 116′, respectively, in the D1 direction. In contrast, the outer spacers 163 and 163′ may be on and directly contact the lower inner spacers 161 and 161′ and the lower channel layers 112 and 112′, respectively, in the D2 direction.

The removal of the portion of the sacrificial layers 111, 111′, 121 and 121′ and the portions of the channel spacers 116 and 116′ may be performed through, for example, wet etching using hydrofluoric acid, not being limited thereto, that selectively removes SiGe against Si forming the channel layers 112, 122, 112′ and 122′ and the material, e.g., silicon nitride, forming the middle isolation layers 140 and 140′. The formation of the inner spacers 161, 162, 161′ and 162′ and the outer spacers 163 and 163′ may be performed through, for example, atomic layer deposition (ALD) of an isolation material such as silicon nitride (e.g., SiN or Si3N4), SiBCN, SiCN, SiOC, SiON, SiBC, SiBN or SiOCN, a combination thereof, not being limited thereto.

Although the channel spacers 116 and 116′ and the sacrificial layers 111, 111′, 121 and 121′ are formed at different steps, the removal of the portions of the channel spacers 116 and 116′ and the removal of the portions of the sacrificial layers 111, 111′, 121 and 121′ to provide the spaces for the inner spacers 161, 162, 161′ and 162′ and the outer spacers 163 and 163′ may be performed at the same time using the same method in the present step as they are formed of the same material, e.g., SiGe having the same Ge concentration.

The inner spacers 161, 162, 161′ and 162′ and the outer spacers 163 and 163′ may be formed of the same isolation material which may also be the same as or different from the isolation material forming the middle isolation layers 140 and 140′. The inner spacers 161, 162, 161′ and 162′ and the outer spacers 163 and 163′ may be formed to have equal lengths in the D1 direction as shown in FIGS. 6O and 6P to be described later.

Since the inner spacers 161, 162, 161′ and 162′ and the outer spacers 163 and 163′ may be formed by the same deposition operation using the same isolation material in this step, lower-left inner spacers 161 formed on the lower-left sacrificial layers 111 and a left outer spacer 163 formed on the left channel spacer 116 may form a single continuum or integral structure without a connection surface, interface or junction therebetween. Similarly, lower-right inner spacers 161′ formed on the lower-right sacrificial layers 111′ and a right outer spacer 163′ formed on the right channel spacer 116′ may form a single continuum or integral structure without a connection surface, interface or junction therebetween. Non-formation of the connection surface, interface or junction may be viewed through cross-sectional transmission electron microscopy (TEM) or scanning electron microscopy (SEM).

Further, a portion of each of the lower-left channel layers 112 may be surrounded by the lower-left inner spacers 161 and the left outer spacer 163, and a portion of each of the lower-right channel layers 112′ may be surrounded by the lower-right inner spacers 161′ and the right outer spacers 163′. The left outer spacer 163 may directly contact side surfaces of the lower-left channel layers 112, and the right outer spacer 163′ may directly contact side surfaces of the lower-right channel layers 112′.

In the meantime, due to the aforementioned channel stack offset, the left outer spacer 163 on a right side of the lower-left channel stack C11 may be formed below and overlapped by the right portion of the upper-left channel stack C21 in the D3 direction. Similarly, the right outer spacer 163′ on a left side of the lower-right channel stack C12 may be formed below and overlapped by the left portion of the upper-right channel stack C22 in the D3 direction.

Referring to FIG. 6N, a lower-left source/drain region 113A, a lower-right source/drain region 113A′, an upper-left source/drain region 123A, and ant upper-right source/drain region 123A′ may be formed on the lower-left channel layers 112, the lower-right channel layers 112′, the upper-left channel layers 122, and the upper-right channel layers 122′, respectively.

Due to the channel stack offset, the lower-left source/drain region 113A and the upper-left source/drain region 123A may also be offset in the D2 direction such that a right portion of the upper-left source/drain region 123A does not overlap the lower-left source/drain region 113A and a left portion of the lower-left source/drain region 113A is not overlapped by the upper-left source/drain region 123A, in the D3 direction. Similarly, 1^{st} lower-right source/drain region 113A′ and the upper-right source/drain region 123A′ may also be offset in the D2 direction such that a left portion of the upper-left source/drain region 123A′ does not overlap the lower-right source/drain region 113A′ and a right portion of the lower-right source/drain region 113A′ is not overlapped by the upper-right source/drain region 123A′, in the D3 direction

The formation of the source/drain regions 113A, 113A′, 123A and 123A′ may be performed through, for example, epitaxial growth of the corresponding channel layers 112, 112′, 122 and 122′, respectively, in one of the spaces S1 formed in the step of FIG. 6K.

FIGS. 6O and 6P illustrate cross-section views taken along lines I-I′ and II-II′ shown in FIG. 6N, respectively.

Referring to FIGS. 6O and 6P a lower-left source/drain region 113B along with the lower-left source/drain region 113A may be formed from the lower-left channel layers 112 while the lower-left sacrificial layers 111 are blocked by the lower-left inner spacers 161. Further, an upper-left source/drain region 123B along with the upper-left source/drain region 123A may be formed from the upper-left channel layers 122 while the upper-left sacrificial layers 121 are blocked by the upper-left inner spacers 162.

Further, FIGS. 6O and 6P show that while the lower-left inner spacers 161 contact the lower-left sacrificial layers 111, respectively, in the D1 direction, and the left outer spacer 163 contacts the left channel spacer 116 in the D1 direction. As the lower-left inner spacers 161 and the left outer spacer 163 may have an equal length in the D1 direction, the patterned left sacrificial layers 111 and 121 and the patterned left channel spacer 116 may have an equal length in the D1 direction.

Referring to FIG. 6Q, the dummy gate structure 150D, the sacrificial layers 111, 121, 111′ and 121′, and the channel spacers 116 and 116′ may be removed and replaced by the gate structure 150.

The removal of the dummy gate structure 150D of polysilicon, the sacrificial layers 111, 121, 111′ and 121′ and the channel spacers 116 and 116′ of SiGe may be performed through, for example, wet etching using an etchant including hydrofluoric acid, not being limited thereto. Subsequently, a gate structure 150 may be formed to fill spaces provided by the removal of the dummy gate structure 150D, the sacrificial layers 111, 121, 111′ and 121′, and the channel spacers 116 and 116′ through, for example, ALD, CVD and/or physical vapor deposition (PVD) of gate materials including at least one of tungsten (W), aluminum (Al), titanium (Ti), tantalum (Ta), etc. and an alloy thereof.

As the dummy gate structure 150D, the sacrificial layers 111, 121, 111′ and 121′, and the channel spacers 116 and 116′ are replaced by the gate structure 150, the lower-left channel stack C11 and the upper-left channel stack C21 may form a lower-left channel structure and an upper-left channel structure, respectively, for a 1^{st} multi-stack transistor structure 600A having a Z-shape, and the lower-right channel stack C12 and the upper-right channel stack C22 may form a lower-right channel structure and an upper-right channel structure, respectively, for a 2^{nd} multi-stack transistor structure 600B which is a flipped form of the 1^{st} multi-stack transistor structure 600A.

Referring to FIG. 6R, the gate structure 150 surrounding the 1^{st} multi-stack transistor structure 600A and the 2^{nd} multi-stack transistor structure 600B may be divided by a gate-cut operation and interconnect structures may be formed for the two multi-stack transistor structures 600A and 600B to finish a semiconductor device 600.

The gate-cut operation may include an etching (e.g., RIE) operation to form a recess in the gate structure 150 between the two multi-stack transistor structures 600A and 600B based on hard mask patterns formed on a top surface of the gate structure 150, and deposition (e.g., PVD, CVD, etc.) of an isolation material in the recess to form a gate-cut structure 180. The isolation material forming the gate-cut structure may include silicon nitride (e.g., Si₃N₄), silicon oxide (e.g., SiO₂), SiON, SiCOH, etc.

The interconnect structures formed for the 1^{st} multi-stack transistor structure 600A may include backside power rails P01 and P02, backside metal lines M01-M03 therebetween, frontside power rails P11 and P12, and frontside metal lines M11-M14 therebetween. The interconnect structures formed for the 2^{nd} multi-stack transistor structure 600B may include the backside power rail P02, which is shared with the 1^{st} multi-stack transistor structure 600A, and a backside power rail P01′ and backside metal lines M01′-M03′ therebetween, the frontside power rail P12, which is shared with the 1^{st} multi-stack transistor structure 400A, and a frontside power rail P11′ and frontside metal lines M11′-M14′ therebetween.

The semiconductor device 600 including the two multi-stack transistor structures 600A and 600B may be the same as or correspond to the semiconductor device 400 of FIG. 4.

FIGS. 6S and 6T illustrate cross-section views taken along lines III-III′ and IV-IV′ shown in FIG. 6R, respectively.

Referring to FIGS. 6S and 6T, while the lower-left inner spacers 161 directly contact a lower portion of the gate structure 150 in the D1 direction, the left outer spacer 163 may also directly contact the lower portion of the gate structure 150 in the D1 direction.

In the meantime, referring back to FIG. 6R, the lower-left portion of the gate structure 150 on the lower-left channel layers 112 may be isolated from an upper-left portion of the gate structure 150 surrounding the upper-left channel layers 122 when the lower-left channel stack C11 and the upper-left channel stack C21 form two nanosheet transistors with respective gate structures isolated from each other. Similarly, a lower-right portion of the gate structure 150 on the lower-right channel layers 112′ may be isolated from an upper-right portion of the gate structure 150 surrounding the upper-right channel layers 122′ when the lower-right channel stack C12 and the upper-right channel stack C22 form two nanosheet transistors with respective gate structures isolated from each other.

In the above-described embodiments, two multi-stack transistor structures 600A and 600B are manufactured using a spacer structure formed between two lower channel stacks so that the two multi-stack transistor structures may each have a Z-shape and face each other in a flipped form in the D2 direction. However, the disclosure is not limited thereto. For example, a single multi-stack transistor structure corresponding to the multi-stack transistor structure 600A or 600B may also be formed to have a Z-shape based on a spacer structure.

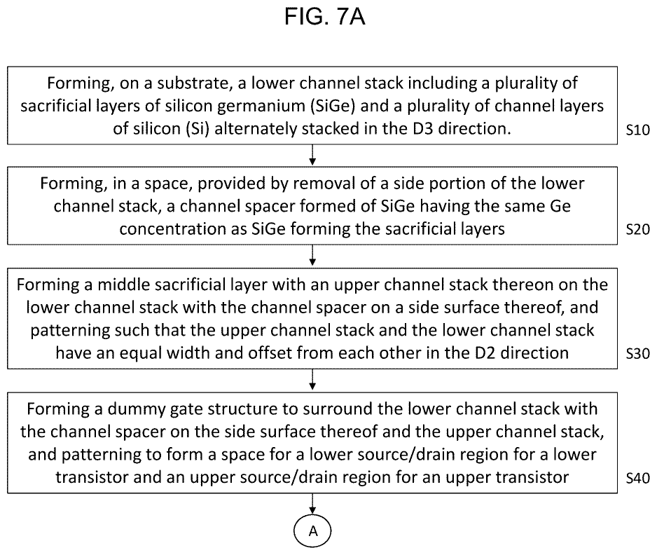

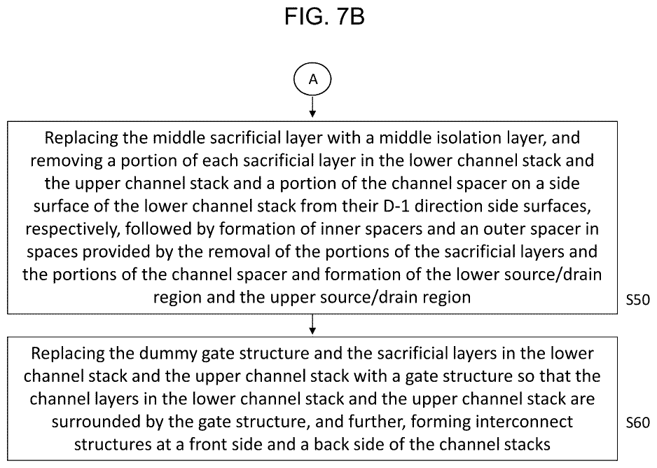

FIGS. 7A and 7B illustrate a flowchart of a method of manufacturing a semiconductor device including a multi-stack transistor structure having a Z-shape and including an outer spacer having a same material as inner spacers, according to one or more embodiments.

The semiconductor device manufactured according to the flowchart of FIGS. 7A and 7B may be the same as or correspond to the multi-stack transistor structure 600A or 600B shown FIGS. 6R-6T, and thus, duplicate descriptions thereof may be omitted herein.

In step S10, a lower channel stack may be formed on a substrate. The lower channel stack may include a plurality of sacrificial layers of silicon germanium (SiGe) and a plurality of channel layers of silicon (Si) that are alternately stacked on the substrate in the D3 direction (FIG. 6A).

In step S20, a side portion of the lower channel stack may be removed, and a channel spacer may be formed in a space provided by the removal of the side portion of the lower channel stack (FIGS. 6B and 6C). Further, the channel spacer may be planarized at the top so that a top surface thereof is coplanar or aligned with a top surface of the lower channel stack in the D1 or D2 direction. The channel spacer may be formed of SiGe having the same Ge concentration as SiGe forming the sacrificial layers.

In step S30, a middle sacrificial layer with an upper channel stack thereon may be formed on the lower channel stack with the channel spacer on a side surface thereof, and patterned such that the upper channel stack and the lower channel stack have an equal width in the D2 direction and offset from each other in the D2 direction (FIGS. 6D-6I).

The channel stack offset may be achieved such that a left or right portion of the upper channel stack is formed above the channel spacer (FIG. 6I), and thus, the left or right portion of the upper channel stack does not overlap the lower channel stack, in the D3 direction (FIG. 6I). As the left or right portion of the upper channel stack does not overlap the lower channel stack, a right or left portion of the lower channel stack is not overlapped by the upper channel stack in the D3 direction (FIG. 6I).

In step S40, the lower channel stack with the channel spacer on the side surface thereof and the upper channel stack may be surrounded by a dummy gate structure, and patterned along with the dummy gate structure thereon to form a space where a lower source/drain region for a lower transistor and an upper source/drain region for an upper transistor are to be formed (FIGS. 6J and 6K).

In step S50, the middle sacrificial layer may be replaced by a middle isolation layer, and a portion of each sacrificial layer in the lower channel stack and the upper channel stack and a portion of the channel spacer on a side surface of the lower channel stack may be removed from their D-1 direction side surfaces, respectively, followed by formation of inner spacers and an outer spacer in spaces provided by the removal of the portions of the sacrificial layers and the portions of the channel spacer and formation of the lower source/drain region and the upper source/drain region (FIGS. 6L-6P)

The inner spacers and the outer spacer may be formed at the same or substantially the same time through, for example, deposition of a same isolation material such as silicon nitride, not being limited thereto, and thus, no connection surface, interface or junction may be formed therebetween. The isolation material forming the inner spacers and the outer spacer may be different from an isolation material forming the middle isolation layer which may be SiBCN.

In step S60, the dummy gate structure and the sacrificial layers in the lower channel stack and the upper channel stack may be removed and replaced by a gate structure so that the channel layers in the lower channel stack and the upper channel stack are surrounded by the gate structure, and further, interconnect structures may be formed at a front side and a back side of the lower channel stack and upper channel stack. Each of the frontside interconnect structure and the backside interconnect structure may be formed to include power rails and metal lines (FIGS. 6Q-6T).

Through the above steps described in reference to FIGS. 6A-6T, 7A and 7B, a semiconductor device may be manufactured to include one or more Z-shaped multi-stack transistor structures and interconnect structures at both a front side and a back side of the semiconductor device.

In the above embodiments described in reference to FIGS. 6A-6T, the channel spacers 116 and 116′, used to manufacture the Z-shaped multi-stack transistor structure 600A and its flipped form, that is the multi-stack transistor structure 600B, may be formed of SiGe having the same or substantially the same Ge concentration (e.g., 25-30%) as the SiGe forming the sacrificial layers 111, 111′, 121 and 121′. Thus, the removal of the channel spacers 116 and 116′ to form the outer spacers 163 and 163′ may be performed at the same or substantially the same time as the removal of portions of the sacrificial layers 111, 111′, 121 and 121′ to form the inner spacers 161, 161′, 162 and 162′, respectively, through the same operation using the same etchant in the step of FIG. 6M. However, the disclosure is not limited thereto, and the following embodiments provide a method using channel spacers formed of SiGe having the same or substantially the same Ge concentration (e.g., 40-45%) as the SiGe forming the initial middle sacrificial layer 104 which is higher than that in the SiGe forming the sacrificial layers 111, 111′, 121 and 121′.

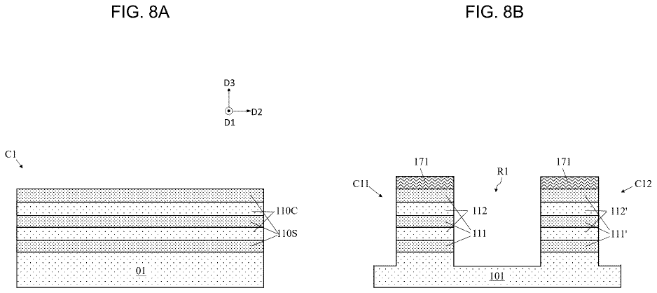

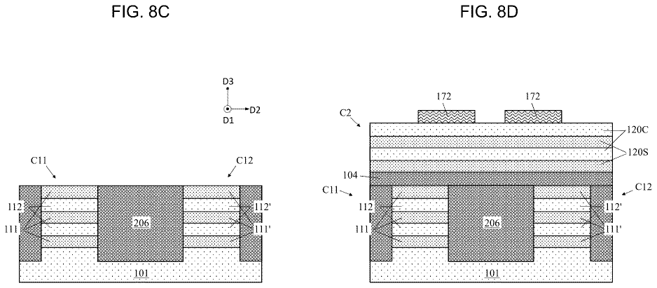

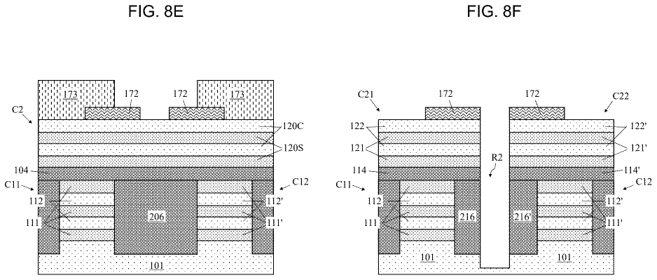

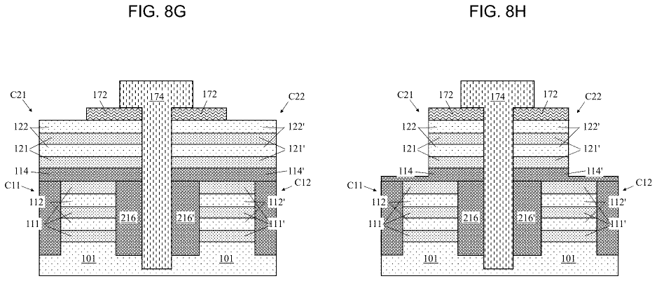

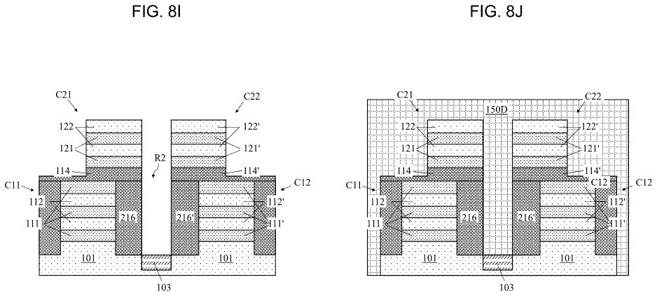

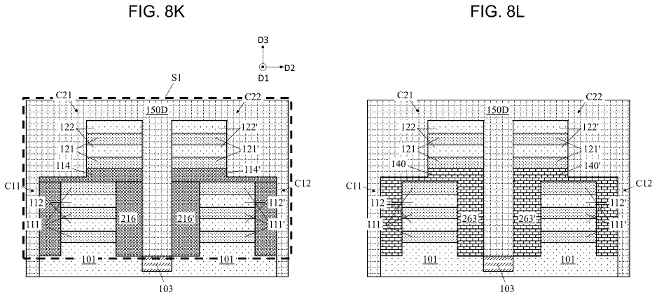

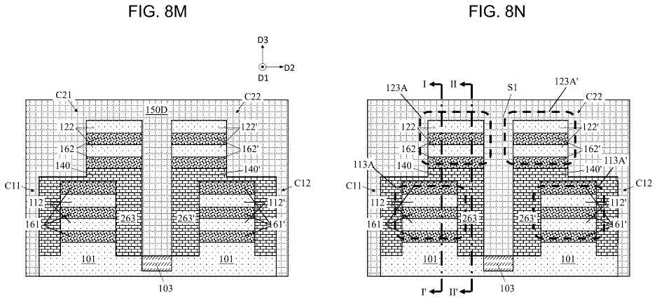

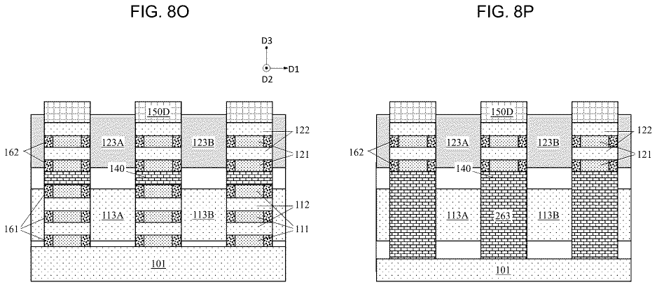

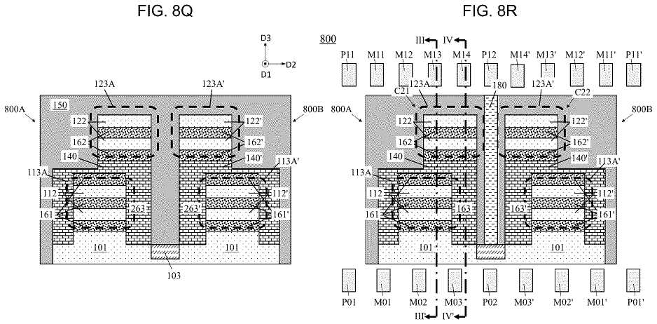

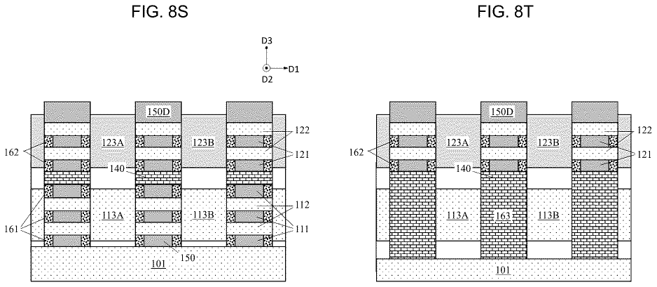

FIGS. 8A-8T illustrate intermediate semiconductor devices obtained after respective steps of manufacturing a semiconductor device including multi-stack transistor structures, both Z-shaped and each being a flipped form of the other and including an outer spacer having a same material as a middle isolation layer, according to one or more other embodiments.

It is to be understood herebelow that, when structural elements of the intermediate semiconductor devices described herebelow in reference to FIGS. 8A-8T are the same as those of the intermediate semiconductor devices described in reference to FIGS. 6A-6T in terms of materials forming thereof, the same reference numerals and characters are used to assist understanding of the intermediate semiconductor devices.

It is to be understood herebelow that, when the intermediate semiconductor devices shown in FIGS. 8A-8T are the same as the intermediate semiconductor devices described in reference to FIGS. 6A-6T in terms of materials and methods forming structural elements thereof, the same reference numerals and characters are used and duplicate descriptions thereof may be omitted herein to assist understanding of the intermediate semiconductor devices of FIGS. 8A-8T.

Referring to FIG. 8A, an initial channel stack C1 may be formed by growing a plurality of lower sacrificial layers 110S and a plurality of channel layers 110C on a substrate 101.

Referring to FIG. 8B, a lower-left channel stack C11 including lower-left sacrificial layers 111 and lower-left channel layers 112 and a lower-right channel stack C12 including lower-right sacrificial layers 111′ and lower-right channel layers 112′ may be formed on a substrate 101 with a 1^{st} recess R1 therebetween.

Referring to FIG. 8C, a spacer structure 206 formed of SiGe having Ge concentration (e.g., 40-45%) higher than Ge concentration (e.g., 25-30%) in SiGe forming the lower sacrificial layers 111 and 111′ may be formed in the recess R1.

Referring to FIG. 8D, an initial middle sacrificial layer 104 form of SiGe having the same or substantially the same Ge concentration (e.g., 40-45%) as the spacer structure 206 may be formed on the lower channel stacks C11 and C12 with the spacer structure 206 therebetween followed by formation of 2^{nd} hard mask patterns 172 on an uppermost upper channel layer 120C.

Referring to FIGS. 8E, 3^{rd} hard mask patterns 173 may be formed on a top surface of the intermediate semiconductor device obtained in the previous step.

Referring to FIG. 8F, the intermediate semiconductor device obtained in the previous step may be patterned based on the 2^{nd} hard mask patterns 172 and the 3^{rd} hard mask patterns 173 to form a 2^{nd} recess R2 dividing the intermediate semiconductor device into two intermediate semiconductor devices respectively including an upper-left channel stack C21 including a left middle sacrificial layer 114, upper-left sacrificial layers 121 and channel layers 122 and an upper-right channel stack C22 including a right middle sacrificial layer 114′, upper-right sacrificial layers 121′ and channel layers 122′.

Referring to FIGS. 8G and 8H, a 4^{th} hard mask pattern 174 may be formed in the 2^{nd} recess R2, and, based on the 4^{th} hard mask pattern 174 and the 2^{nd} hard mask patterns 172, the upper-left channel stack C21 and the upper-right channel stack C22 may be patterned.

Referring to FIG. 8I, the 4^{th} hard mask pattern 174 and the 2^{nd} hard mask patterns 172 may be removed and the 2^{nd} recess R2 is reopened, followed by formation of a shallow trench isolation (STI) structure 103 at a lower portion of the 2^{nd} recess R2.

Referring to FIG. 8J, a dummy gate structure 150D may be formed to surround the intermediate semiconductor device obtained in the previous step.

Referring to FIG. 8K, the intermediate semiconductor device obtained in the previous step may be patterned to form a space S1 where left source/drain regions and right source/drain regions are to be formed in a later step.

Referring to FIG. 8L, the middle sacrificial layer 114 and 114′ and the channel spacers 216 and 216′ formed of the same SiGe with the same or substantially the same Ge concentration may be removed through, for example, wet etching using hydrofluoric acid as etchant or dry etching using fluorine-based plasma as etchant, followed by formation of middle isolation layer 140 and 140′ and outer spacers 263 and 263′ in spaces provided by the removals of the middle sacrificial layer 114 and 114′ and the channel spacers 216 and 216′.

The middle isolation layer 140 and 140′ and outer spacers 263 and 263′ may be formed at the same or substantially the same time through a same method, such as CVD, PECVD, ALD, etc., of a same isolation layer material, such as silicon nitride (e.g., SiN or Si₃N₄), SiBCN, SiCN, SiOC, SiON, SiBC, SiBN or SiOCN, a combination thereof, not being limited thereto. Thus, the left outer spacer 263 and the left middle isolation layer 140 may form a single continuum or integral structure without a connection surface, interface or junction therebetween. Similarly, the right outer spacer 263′ and the right middle isolation layer 140′ may form a single continuum or integral structure without a connection surface, interface or junction therebetween. Non-formation of a connection surface, interface or junction may be viewed through cross-sectional transmission electron microscopy (TEM) or scanning electron microscopy (SEM).

Here, as the channel spacers 216 and 216′, the middle sacrificial layers 114 and 114 , and the channel stacks C11, C21, C12 and C22 shown in FIG. 8K have equal lengths in the D1 direction, the outer spacers 263 and 263′, the middle isolation layers 140 and 140′ and the channel stacks C11, C21, C12 and C22 may also have equal lengths in the D1 direction as shown in FIGS. 8O and 8P to be described later. This is different from the intermediate semiconductor device shown in FIGS. 6A-6T, where the outer spacers 163 and 163′ have lengths equal to those of the inner spacers 161 and 162 in the D1 direction.

Referring to FIGS. 8M and 8N, inner spacers 161, 162, 161′ and 162′ may be formed, followed by formation of a lower-left source/drain region 113A, a lower-right source/drain region 113A′, an upper-left source/drain region 123A, and an upper-right source/drain region 123A′ on the lower-left channel layers 112, the lower-right channel layers 112′, the upper-left channel layers 122, and the upper-right channel layers 122′, respectively.

As the inner spacer 161, 162, 161′ and 162′ are formed, a portion of each of the lower-left channel layers 112 may be surrounded by the lower-left inner spacers 161 and the left outer spacer 263, and a portion of each of the lower-right channel layers 112′ may be surrounded by the lower-right inner spacers 161′ and the right outer spacers 263′. The left outer spacer 263 may directly contact side surfaces of the lower-left sacrificial layers 111 and channel layers 112, and the right outer spacer 263′ may directly contact side surfaces of the lower-right sacrificial layers 111′ and channel layers 112′.

FIGS. 8O and 8P illustrate cross-section views taken along lines I-I′ and II-II′ shown in FIG. 8N, respectively.

FIGS. 8O and 8P show that while the lower-left inner spacers 161 directly contact the lower-left sacrificial layers 111, respectively, in the D1 direction, the left outer spacer 163 may extend in the D1 direction to directly contact the patterned lower-left sacrificial layers 111 and lower-left channel layers 112 in the D2 direction and may have an equal length as each of the lower-left channel layers 112 and as a sum of each of the lower-left sacrificial layers 111 and two lower-left inner spacers 161 in the D1 direction.

In the meantime, the lower portion of the gate structure 150 on the lower-left channel layers 112 may be isolated from an upper portion of the gate structure 150 surrounding the upper-left channel layers 122.

Referring to FIG. 8Q, the dummy gate structure 150D and the sacrificial layers 111, 121, 111′ and 121′ may be removed and replaced by the gate structure 150 to form a 1^{st} multi-stack transistor structure 800A in a Z-shape and a 2^{nd} multi-stack transistor structure 600B which is a flipped form of the 1^{st} multi-stack transistor structure 800A.

Referring to FIG. 8R, the gate structure 150 surrounding the 1^{st} multi-stack transistor structure 600A and the 2^{nd} multi-stack transistor structure 600B may be divided by a gate-cut structure 180 and interconnect structures including power rails and metal lines P01, P02, P01′, P11, P12, M01-M03, M01′-M03′, M11-M14 and M11′-M14′ may be formed for the two multi-stack transistor structures 800A and 800B to finish a semiconductor device 800.

The semiconductor device 800 including the two multi-stack transistor structures 600A and 600B may be the same as or correspond to the semiconductor device 400 of FIG. 4.

FIGS. 8S and 8T illustrate cross-section views taken along lines III-III′ and IV-IV′ shown in FIG. 6R, respectively.

Referring to FIGS. 8S and 8T along with FIG. 8R, while the lower-left inner spacers 161 directly contact a lower-left portion of the gate structure 150 in the D1 direction, the left outer spacer 163 may extend in the D1 direction to directly contact the lower-left portion of the gate structure 150 and lower-left channel layers 112 in the D2 direction and may have an equal length as each of the lower-left channel layers 122 and as a sum of the lower-left portion of the gate structure 150 and two lower-left inner spacers 161 in the D1 direction.

In the meantime, referring back to FIG. 8R, the lower-left portion of the gate structure 150 on the lower-left channel layers 112 may be isolated from an upper-left portion of the gate structure 150 surrounding the upper-left channel layers 122 when the lower-left channel stack C11 and the upper-left channel stack C21 form two nanosheet transistors with respective gate structures isolated from each other. Similarly, a lower-right portion of the gate structure 150 on the lower-right channel layers 112′ may be isolated from an upper-right portion of the gate structure 150 surrounding the upper-right channel layers 122′ when the lower-right channel stack C12 and the upper-right channel stack C22 form two nanosheet transistors with respective gate structures isolated from each other.

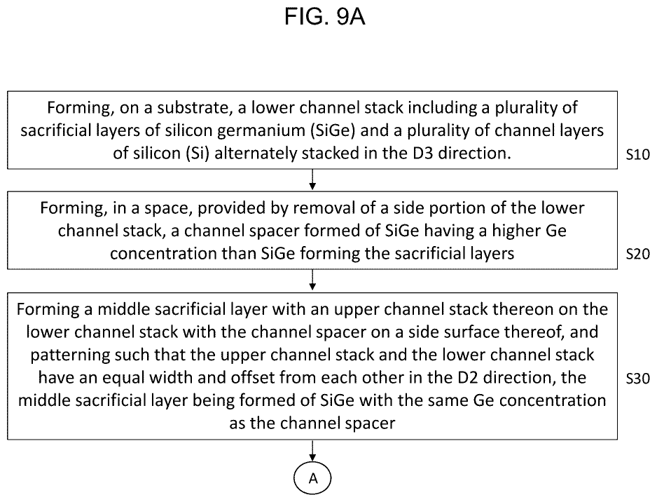

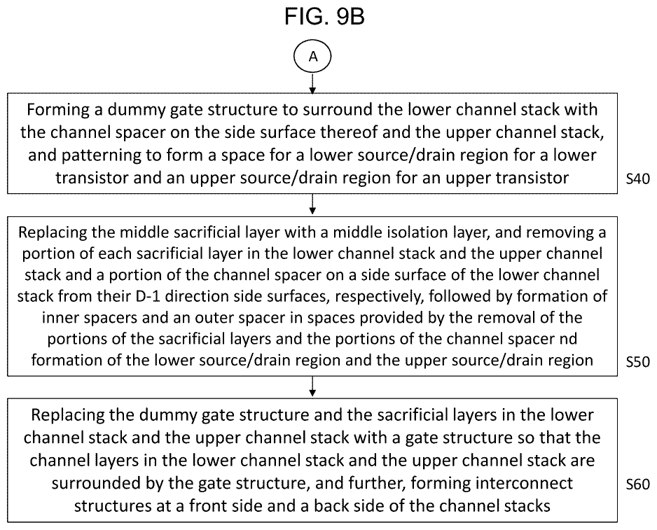

FIGS. 9A and 9B illustrate a flowchart of a method of manufacturing a semiconductor device including a multi-stack transistor structure having a Z-shape and including an outer spacer having a same material as a middle isolation layer, according to one or more other embodiments.

The semiconductor device manufactured according to the flowchart of FIGS. 9A and 9B may be the same as or correspond to the multi-stack transistor structure 800A or 800B shown FIGS. 8R-8T, and thus, duplicate descriptions thereof may be omitted herein.

In step S10, a lower channel stack may be formed on a substrate. The lower channel stack may include a plurality of sacrificial layers of silicon germanium (SiGe) and a plurality of channel layers of silicon (Si) that are alternately stacked on the substrate in the D3 direction (FIG. 8A).

In step S20, a side portion of the lower channel stack may be removed, and a channel spacer may be formed in a space provided by the removal of the side portion of the lower stack (FIGS. 8B and 8C). Further, the channel spacer may be planarized at the top so that a top surface thereof is coplanar or aligned with a top surface of the lower channel stack in the D1 or D2 direction. The channel spacer may be formed of SiGe having a Ge concentration higher than that in SiGe forming the sacrificial layers.

In step S30, a middle sacrificial layer with an upper channel stack thereon may be formed on the lower channel stack with the channel spacer on a side surface thereof, and patterned such that the upper channel stack and the lower channel stack have an equal width in the D2 direction and offset from each other in the D2 direction (FIGS. 8D-8I). The middle sacrificial layer may be formed of SiGe having the same Ge concentration as that in the SiGe forming the channel spacer.

The channel stack offset may be achieved such that a left or right portion of the upper channel stack is formed above the channel spacer, and thus, the left or right portion of the upper channel stack does not overlap the lower channel stack, in the D3 direction, and a right or left portion of the lower channel stack is not overlapped by the upper channel stack in the D3 direction.

In step S40, the lower channel stack with the channel spacer on the side surface thereof and the upper channel stack may be surrounded by a dummy gate structure, and patterned along with the dummy gate structure thereon to form a space where a lower source/drain region for a lower transistor and an upper source/drain region for an upper transistor are to be formed (FIGS. 8J and 8K).

In step S50, the middle sacrificial layer and the channel spacer formed of the same Ge with the same Ge concentration may be replaced by a middle isolation layer and an outer spacer formed of a same isolation material, and a portion of each sacrificial layer in the lower channel stack and the upper channel stack may be removed from its D-1 direction side surface, followed by formation of inner spacers provided by the removal of the portions of the sacrificial layers and formation of the lower source/drain region and the upper source/drain region (FIGS. 8L-8P)

The middle isolation layer and the outer spacer may be formed at the same or substantially the same time through, for example, deposition of the same isolation material such as SiBCN, not being limited thereto, and thus, no connection surface, interface or junction may be formed therebetween. The isolation material forming the middle isolation layer and the outer spacer may be different from an isolation material forming the inner spacers, which may be silicon nitride.

In step S60, the dummy gate structure and the sacrificial layers in the lower channel stack and the upper channel stack may be removed and replaced by a gate structure so that the channel layers in the lower channel stack and the upper channel stack are surrounded by the gate structure, and further, interconnect structures may be formed at a front side and a back side of the lower channel stack and upper channel stack. Each of the frontside interconnect structure and the backside interconnect structure may be formed to include power rails and metal lines (FIGS. 8Q-8T).

Through the above steps described in reference to FIGS. 8A-8T, 9A and 9B, a semiconductor device may be manufactured to include one or more Z-shaped multi-stack transistor structures and interconnect structures at both a front side and a back side of the semiconductor device.

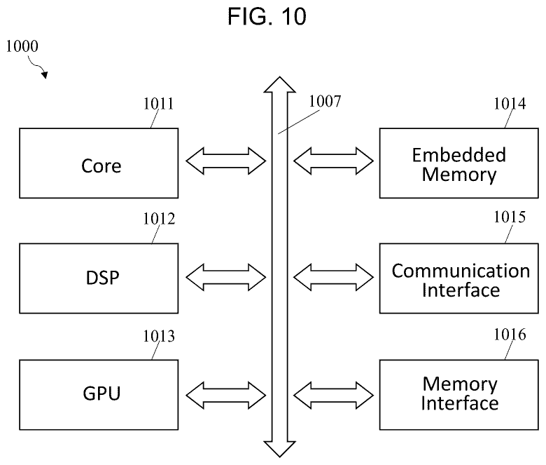

FIG. 10 is a schematic block diagram illustrating an electronic device including a semiconductor device in which one or more Z-shape multi-stack transistor structures are formed, according to one or more embodiments. The semiconductor device may be one of the semiconductor devices 200, 300, 400, 600 and 800 described above.

Referring to FIG. 10, an SoC 1000 may be an integrated circuit in which components of a computing system or other electronic systems are integrated. As an example of the SoC 1000, an application processor (AP) may include at least one processor and components for various functions. The SoC 1000 may include a core 1011 (e.g., a processor), a digital signal processor (DSP) 1012, a graphic processing unit (GPU) 1013, an embedded memory 1014, a communication interface 1015, and a memory interface 1016. The components of the SoC 1000 may communicate with each other through a bus 1007.

The core 1011 may process instructions and control operations of the components included in the SoC 1000. For example, the core 1011 may process a series of instructions to run an operating system and execute applications on the operating system. The DSP 1012 may generate useful data by processing digital signals (e.g., a digital signal provided from the communication interface 1015). The GPU 1013 may generate data for an image output by a display device from image data provided from the embedded memory 1014 or the memory interface 1016, or may encode the image data.

The embedded memory 1014 may store data necessary for the core 1011, the DSP 1012, and the GPU 1013 to operate. The communication interface 1015 may provide an interface for a communication network or one-to-one communication. The memory interface 1016 may provide an interface for an external memory of the SoC 1000, such as a dynamic random access memory (DRAM), a flash memory, etc.

At least one of the core 1011, the DSP 1012, the GPU 1013, and/or the embedded memory 1014 may include a semiconductor device which may be one of the semiconductor devices 200, 300, 400, 600 and 800 described above.

The foregoing is illustrative of example embodiments and is not to be construed as limiting the disclosure. Although a few example embodiments have been described, those skilled in the art will readily appreciate that many modifications are possible in the above embodiments without materially departing from the disclosure.

What is claimed is:

1. A semiconductor device comprising:
a 1^{st} transistor comprising a 1^{st} channel structure and a 1^{st} source/drain region connected to the 1^{st} channel structure in a 1^{st} direction intersecting a 2^{nd} direction; and
a 2^{nd} transistor comprising a 2^{nd} channel structure and a 2^{nd} source/drain region connected to the 2^{nd} channel structure in the 1^{st} direction,
wherein the 2^{nd} transistor is above the 1^{st} transistor in a 3^{rd} direction intersecting the 1^{st} direction and the 2^{nd} direction, and
wherein a portion of the 1^{st} channel structure is not overlapped by the 2^{nd} channel structure and a portion of the 2^{nd} channel structure does not overlap the 1^{st} channel structure, in the 3^{rd} direction.

2. The semiconductor device of claim 1, further comprising:
a 1^{st} gate structure on the 1^{st} channel structure;
a 1^{st} inner spacer between the 1^{st} gate structure and the 1^{st} source/drain region in the 1^{st} direction; and
a 1^{st} outer spacer contacting the 1^{st} inner spacer and the 1^{st} channel structure in the 2^{nd} direction.

3. The semiconductor device of claim 2, wherein the 1^{st} channel structure and the 2^{nd} channel structure have an equal width in the 2^{nd} direction.

4. The semiconductor device of claim 2, wherein the portion of the 2^{nd} channel structure that does not overlap the 1^{st} channel structure is above the 1^{st} outer spacer in the 3^{rd} direction.

5. The semiconductor device of claim 2, wherein the 1^{st} outer spacer and the 1^{st} inner spacer have an equal length in the 1^{st} direction.

6. The semiconductor device of claim 2, wherein the 1^{st} outer spacer and the 1^{st} inner spacer comprise a same material.

7. The semiconductor device of claim 2, wherein the 1^{st} outer spacer and the 1^{st} inner spacer are connected without a connection surface, interface or junction therebetween.

8. The semiconductor device of claim 2, further comprising a middle isolation layer between the 1^{st} channel structure and the 2^{nd} channel structure in the 3^{rd} direction,
wherein the middle isolation layer comprises a material different from a material included in the 1^{st} outer spacer.

9. The semiconductor device of claim 2, wherein the 1^{st} outer spacer has a length greater than a length of the 1^{st} inner spacer in the 1^{st} direction.

10. The semiconductor device of claim 2, wherein the 1^{st} outer spacer comprises a material different from a material included in the 1^{st} inner spacer.

11. The semiconductor device of claim 2, further comprising a middle isolation layer between the 1^{st} channel structure and the 2^{nd} channel structure in the 3^{rd} direction,
wherein the middle isolation layer comprises a material which is the same as the material included in the 1^{st} outer spacer.

12. The semiconductor device of claim 2, further comprising a middle isolation layer between the 1^{st} channel structure and the 2^{nd} channel structure in the 3^{rd} direction,
wherein the middle isolation layer and the 1^{st} outer spacer are connected without a connection surface, interface or junction therebetween.

13. The semiconductor device of claim 2, wherein the 1^{st} outer spacer contacts the 1^{st} gate structure in the 2^{nd} direction.

14. The semiconductor device of claim 1, further comprising:
a frontside power rail and a frontside metal line above the 2^{nd} channel structure in the 3^{rd} direction; and
a backside power rail and a backside metal line below the 1^{st} channel structure in the 3^{rd} direction.

15. The semiconductor device of claim 1, further comprising:
a 3^{rd} transistor comprising a 3^{rd} channel structure and a 3^{rd} source/drain region connected to the 3^{rd} channel structure in the 1^{st} direction;
a 4^{th} transistor comprising a 4^{th} channel structure and a 4^{th} source/drain region connected to the 4^{th} channel structure in the 1^{st} direction;
a 2^{nd} gate structure on the 3^{rd} channel structure;
a 2^{nd} inner spacer between the 2^{nd} gate structure and the 3^{rd} source/drain region in the 1^{st} direction; and
a 2^{nd} outer spacer contacting the 2^{nd} inner spacer and the 2^{nd} channel structure in the 2^{nd} direction,
wherein the 4^{th} transistor is above the 3^{rd} transistor in the 3^{rd} direction, and
wherein a set of the 3^{rd} transistor, the 4^{th} transistor, the 2^{nd} inner spacer and the 2^{nd} outer spacer is a flipped form of a set of the 1^{st} transistor, the 2^{nd} transistor, the 1^{st} inner spacer and the 1^{st} outer spacer in the 2^{nd} direction.

16. A semiconductor device comprising:
a 1^{st} transistor comprising a 1^{st} channel structure and a 1^{st} source/drain region connected to the 1^{st} channel structure in a 1^{st} direction intersecting a 2^{nd} direction; and
a 2^{nd} transistor comprising a 2^{nd} channel structure and a 2^{nd} source/drain region connected to the 2^{nd} channel structure in the 1^{st} direction,
wherein the 2^{nd} transistor is above the 1^{st} transistor in a 3^{rd} direction intersecting the 1^{st} direction and the 2^{nd} direction,
wherein the 1^{st} channel structure and the 2^{nd} channel structure have an equal channel width in the 2^{nd} direction intersecting the 1^{st} direction, and
wherein the 2^{nd} channel structure is offset from the 1^{st} channel structure in the 2^{nd} direction.

17. The semiconductor device of claim 16, further comprising:
a 1^{st} gate structure on the 1^{st} channel structure;
a 1^{st} inner spacer between the 1^{st} gate structure and the 1^{st} source/drain region in the 1^{st} direction; and
a 1^{st} outer spacer at a side of the 1^{st} channel structure and the 1^{st} inner spacer in the 2^{nd} direction, below a portion of the 2^{nd} channel structure not overlapping the 1^{st} channel structure in the 3^{rd} direction.

18. The semiconductor device of claim 17, further comprising a middle isolation layer between the 1^{st} channel structure and the 2^{nd} channel structure in the 3^{rd} direction,
wherein the 1^{st} outer spacer comprises a material which is the same as a material included in the 1^{st} inner spacer or a material included in the middle isolation layer.

19. A method of manufacturing a semiconductor device, the method comprising:
forming a 1^{st} channel structure extending in a 1^{st} direction intersecting a 2^{nd} direction; and
forming a 2^{nd} channel structure extending in the 1^{st} direction above the 1^{st} channel structure in a 3^{rd} direction intersecting the 1^{st} direction and the 2^{nd} direction such that a portion of the 1^{st} channel structure is not overlapped by the 2^{nd} channel structure and a portion of the 2^{nd} channel structure does not overlap the 1^{st} channel structure, in the 3^{rd} direction.

20. The method of claim 19, further comprising:
forming an inner spacer on the 1^{st} channel structure;
forming an outer spacer below the portion of the 2^{nd} channel structure not overlapping the 1^{st} channel structure in the 3^{rd} direction; and
forming a 1^{st} source/drain region on the 1^{st} channel structure,
wherein a material forming the outer spacer is the same as or different from a material forming the inner spacer.
